(19) United States
(12) Patent Application Publication
(10) Pub. No.: US 2023/0198506 A1
(43) Pub. Date: Jun. 22, 2023

(54) ARBITRARY SAMPLE RATE CONVERSION USING MODULUS ACCUMULATOR

(71) Applicant: Analog Devices International Unlimited Company, Limerick (IE)

(72) Inventors: Devendra PONNAPUREDDY, Bangalore (IN); Carroll C. SPEIR, Pleasant Garden, NC (US)

(73) Assignee: Analog Devices International Unlimited Company, Limerick (IE)

(21) Appl. No.: 17/884,294

(22) Filed: Aug. 9, 2022

(30) Foreign Application Priority Data
Aug. 11, 2021 (IN) 202141036272

(51) Int. Cl. H03H 17/02; H03H 17/06

(52) U.S. Cl. CPC H03H 17/0275; H03H 17/0685; H03H 17/028

(57) ABSTRACT

Systems, devices, and methods related to a sample rate converter (SRC) for implementing a rate conversion R are provided. The SRC receives input samples at an input rate Fᵢₙ and outputs samples at an output rate Fₒᵤₜ=Fᵢₙ×R, where R is a fractional value greater than 1. The SRC includes a plurality of filters to process the received input samples and a multiplier-adder block to generate the output samples based on respective delta values and outputs of the plurality of filters. The SRC further includes a plurality of buffers to buffer samples between the plurality of filters and the multiplier-adder block based at least in part on N buffer read pointers, where N is an integer greater than 1. The SRC further includes resampler control circuitry to generate N delta values of the delta values and the N buffer read pointers in parallel based on R.

### CROSS REFERENCE TO RELATED APPLICATIONS

The present application claims priority to and the benefit of the Indian Provisional Patent Application No. 202141036272 entitled “ARBITRARY SAMPLE RATE CONVERSION USING MODULUS ACCUMULATOR” and filed Aug. 11, 2021, which is hereby incorporated by reference in its entirety as if fully set forth below and for all applicable purposes.

### TECHNICAL FIELD OF THE DISCLOSURE

The present disclosure generally relates to integrated circuits and, more specifically, to systems, methods, and techniques for performing arbitrary sample rate conversion.

### BACKGROUND

Sample rate conversion is the process of changing the sampling rate of a discrete signal to obtain a new discrete representation of the underlying continuous signal. If the ratio of the input sampling rate and the output sampling rate is or can be approximated by a fixed rational number L/M, sample rate conversion may be performed by generating an intermediate signal by inserting L−1 zeros between each of the original input samples, low-pass filtering this signal at half of the lower of the two sampling rates, and selecting every M-th sample from the filtered output to obtain rate-converted samples.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIG. 1 provides a representation of an example sample rate converter (SRC) block;

FIG. 2 provides a representation of an example SRC that utilizes a polyphase structure;

FIG. 3 provides an example implementation of a polyphase structure-based SRC;

FIG. 4 provides an example fractional SRC (FSRC) that utilizes a hybrid analog/digital (A/D) model;

FIG. 5A provides an example FSRC that utilizes a farrow structure for interpolation;

FIG. 5B is a timing diagram providing an example illustration of delta parameters used by an FSRC;

FIG. 6 provides an example FSRC that utilizes a modified farrow structure for interpolation;

FIG. 7 provides an example FSRC that utilizes a modified farrow structure for decimation;

FIG. 8 provides an example digital hardware implementation for an accumulator for generating delta values for a farrow structure-based FSRC, according to some embodiments of the present disclosure;

FIG. 9 provides another example digital hardware implementation for an accumulator for generating delta values for a farrow structure-based FSRC, according to some embodiments of the present disclosure;

FIG. 10 provides an example farrow structure-based FSRC with a parallel structure for interpolation, according to some embodiments of the present disclosure;

FIG. 11 is a table of example parameters that facilitate sample rate conversion, according to some embodiments of the present disclosure;

FIG. 12 is another table of example parameters that facilitate sample rate conversion, according to some embodiments of the present disclosure;

FIG. 13 provides an example digital hardware implementation for an accumulator with a parallel structure for generating delta values and buffer pointers for a farrow structure-based FSRC, according to some embodiments of the present disclosure;

FIG. 14 provides an example digital hardware implementation scheme for first-in-first-out (FIFO) data transfers, according to some embodiments of the present disclosure;

FIG. 15 provides another example digital hardware implementation scheme for FIFO data transfers, according to some embodiments of the present disclosure;

FIG. 16 provides an example farrow structure-based FSRC with a parallel structure for decimation, according to some embodiments of the present disclosure;

FIG. 17 provides an example digital hardware implementation scheme for integration and dump, according to some embodiments of the present disclosure;

FIG. 18 provides another example digital hardware implementation scheme for integration and dump, according to some embodiments of the present disclosure;

FIG. 19 shows an example finite impulse response (FIR) filter parallel implementation scheme;

FIG. 20 is a flowchart of a method for performing sample rate conversion at high sampling rates for interpolation, according to some embodiments of the present disclosure; and

FIG. 21 is a flowchart of a method for performing sample rate conversion at high sampling rates for decimation, according to some embodiments of the present disclosure.

### DESCRIPTION OF EXAMPLE EMBODIMENTS OF THE DISCLOSURE

Overview

The systems, methods and devices of this disclosure each have several innovative embodiments, no single one of which is solely responsible for all of the desirable attributes disclosed herein. Details of one or more implementations of the subject matter described in this specification are set forth in the description below and the accompanying drawing.

Sample rate conversion is becoming an important component in many applications, for example, including but not limited to, digital mixing consoles, digital audio workstations, digital audio and/or video recorders, digital audio broadcast equipment, multimedia systems, computer system, wireless communication systems. For interpolation, the output sample rate is higher than the input sample rate. On the hand, for decimation, the output sample rate is lower than the input sample rate. Sample rate conversion can be implemented using a wide variety of techniques and/or architectures, such as half-band filters, finite impulse response (FIR) filters, polyphase-based filters, and polynomial-based filters.

The present disclosure provides techniques for performing sample rate conversion using polynomial-based filters. In some aspects, a farrow structure may be used to implement the polynomial-based filters. In some aspects, the generation of a delta value used in the farrow structure may be implemented using a modulus accumulator, for example, implemented using digital hardware logics. The delta value may refer to the fractional sampling time interval parameter, which is commonly referred to as u, in the farrow structure. Because a new delta value is to be calculated for each output sample for interpolation or for each input sample for decimation, it may be difficult or impossible to operate the filters and/or the modulus accumulator when the input/output sampling frequencies are high (e.g., in the GHz range). Accordingly, in some aspects, the delta value generation may be performed at a slower clock rate than the input and/or output sampling frequencies and using a parallel architecture. Further, to facilitate the parallel operations, first-in-first-out (FIFO) buffers may be used for transferring data to or from the polynomial-based filters depending on whether the sample rate conversion is for interpolation or decimation.

In one aspect of the present disclosure, a first sample rate converter (SRC) is provided for implementing a rate conversion R, where R is a fractional value greater than 1, and data is input to the first SRC at an input rate Fᵢₙ and output from the first SRC at an output rate Fₒᵤₜ=Fᵢₙ×R (e.g., for interpolation). The first SRC may include a plurality of filters to process samples received at an input of the first SRC. In some aspects, the plurality of filters may be polynomial-based filters (e.g., farrow filters) and each filter may be associated with a different polynomial order. The first SRC may further include a multiplier-adder block to generate output samples for the first SRC based on respective delta values and outputs of the plurality of filters. Each of the delta values may correspond to a time interval or a time distance (e.g., a fraction of an input sampling time interval) from one of the received input samples.

To enable sample rate conversion for high input/output sample rates (e.g., in the GHz range), the first SRC may operate at a clock rate slower than the input/output sampling rates (e.g., using a clock signal at Fₒᵤₜ/N, where N is an integer greater than 1) and may utilize a parallel implementation scheme. For instance, the first SRC may further include a plurality of buffers (e.g., FIFOs) to buffer (or transfer) samples between the plurality of filters and the multiplier-adder block based at least in part on N buffer read pointers. For instance, each buffer of the plurality of buffers may stores output samples of a respective one of the plurality of filters. The stored samples may be read from each buffer based on the N buffer read pointers. To facilitate the parallel implementation, the first SRC may further include resampler control circuitry to generate N delta values of the delta values and the N buffer read pointers in parallel based on R (e.g., within one clock cycle).

To provide an efficient parallel implementation, the resample control circuitry may increment a base accumulation value by N×1/R and generate the N delta values and the N buffer read pointers based on the incremented base accumulation value. The resample control circuitry may apply a modulo operation to the base accumulation value before the incrementing. That is, the base accumulation value is computed using modulus accumulation. Subsequently, the resampler control circuitry may generate the N delta values by adding k×1/R to the incremented base accumulation value, where k varies from 0 to N−1. In an aspect, the resampler control circuitry may include a base accumulator and N adders coupled to the output of the base accumulator. The base accumulator (e.g., a modulus accumulator) may increment the base accumulation value by N×1/R. Each of the N adders may generate one of the N delta values and an offset for a corresponding buffer read pointer of the N buffer read pointers by adding k×R_int to the incremented base accumulation value, where k varies from 0 to N−1 and R_int corresponds to 1/R represented by a P-bit integer value. In some aspects, an output of an individual adder of the N adders may include a first portion of bits (e.g., lower bits or least-significant-bits (LSBs)) providing a respective one of the N delta values and a second portion of bits (e.g., upper bits or most-significant-bits (MSBs)) providing an offset for a respective one of the N buffer read pointers. In some aspects, the resampler control circuitry may further include N multiplexers (MUXs), each having inputs connected to respective outputs of a first buffer of the plurality of buffers and outputs connected to the multiplier-adder block. The resample control circuitry may further generate a selection signal to each of the N MUXs based on a respective one of the N buffer read pointers.

In another aspect of the present disclosure, a second SRC is provided for implementing a rate conversion R, where R is a fractional value greater than 1, and data is input to the second SRC at an input rate Fᵢₙ and output from the second SRC at an output rate Fₒᵤₜ=Fᵢₙ/R (e.g., for decimation). The second SRC may include a multiplier block to multiply each input sample received at the second SRC by a respective one of delta values. Each of the delta values may correspond to a time interval (e.g., a fraction of an output sampling time interval) from one of output samples of the second SRC. The second SRC may further include integration and dump circuitry to sum outputs of the multiplier block. The second SRC may further include resampler control circuitry to generate N delta values of the delta values and N buffer write pointers in parallel, where N is an integer greater than 1. For instance, the second SRC may utilize a parallel implementation to facilitate rate conversion for high sampling rates (e.g., in the GHz range) where the second SRC may operate at a clock rate of Fᵢₙ/N. The second SRC may further include a plurality of filters (e.g., polynomial-based filters) and a plurality of buffers (e.g., FIFOs) to buffer samples between the integration and dump circuitry and the plurality of filters based at least in part on the N buffer write pointers. As will be discussed more fully below, to enable an efficient parallel implementation, the resampler control circuitry of the second SRC (for decimation) may utilize substantially the same mechanisms as the resampler control circuitry of the first SRC (for interpolation), but the buffer pointer calculation may be used for writing samples to the FIFOs instead of reading samples from the FIFOs.

The systems, schemes, and mechanisms described herein advantageously utilize a parallelization scheme to enable hardware implementation of SRCs for high sampling rates (e.g., in the GHz range). Utilizing modulus accumulation to compute the delta values can provide an accurate or precise sample rate conversion. Additionally, the disclosed arrangement of the base accumulator and the N accumulators for calculating the N delta values and N buffer pointers (e.g., N buffer read pointers for interpolation or N buffer write pointers for decimation) can provide an efficient parallel implementation. Further, the disclosed buffer pointer calculation techniques can allow for a reduced number of multiplexers for accessing the buffers (e.g., for reading from the buffers in interpolation or for writing to the buffers in decimation). The disclosed SRCs may be suitable for use in any suitable applications for arbitrary sampling rate conversion (e.g., fractional sample rate conversion). The disclosed SRCs may be suitable for application where the sample rate change R is to be dynamically configured (e.g., programmed via software and/or firmware).

Example FSRC

A sample rate ratio R may be a rational or irrational number. In any case, the sample rate ratio R may be represented as a fraction L/M, where, for an irrational number, L/M may closely match the actual value based on the precision of L and M.

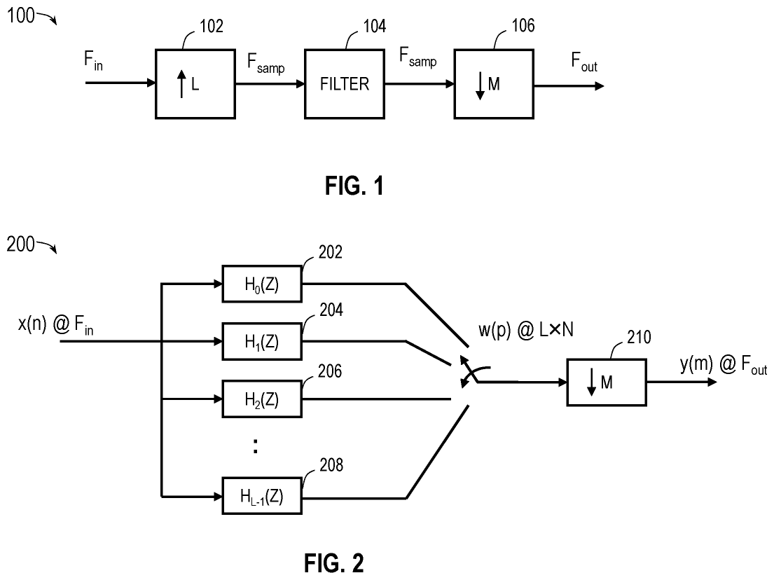

FIG. 1 provides a representation of an example SRC 100 for sample rate conversion by a ratio of L/M. The SRC 100 may include an interpolator 102, a filter 104 and a decimator 106. The interpolator 102 may perform a sample rate up-conversion on an incoming signal by a factor L. The filter 104, e.g., an interpolation filter, may filter the upconverted signal to remove any residuals (e.g., images or aliases) of the original signal in the upconverted signal. The decimator 106 may perform a sample rate down-conversion on the upconverted and filtered signal by a factor M. The overall conversion ratio thus achieved is a ratio of L/M.

In the example FIG. 1, an input signal having an input frequency Fᵢₙ may be input to the interpolator 102. Output of the interpolator 102 may be an intermediate signal having a sample frequency Fₛₐₘₚ. The sample frequency Fₛₐₘₚ may be expressed as Fₛₐₘₚ=L×Fᵢₙ. The input sampling period Tᵢₙ may be expressed as Tᵢₙ=1/Fᵢₙ. Filtering the intermediate signal typically does not change the frequency of the signal, hence the frequency of the intermediate signal after filtering by the filter 104 may remain to be Fₛₐₘₚ. The intermediate signal may be input to the decimator 106. Output of the decimator 106 may be an output signal having an output frequency Fₒᵤₜ. The output frequency may be expressed as Fₒᵤₜ=Fₛₐₘₚ/M=Fᵢₙ×L/M. The output sampling period Tₒᵤₜ may be expressed as Tₒᵤₜ=1/Fₒᵤₜ.

The SRC 100 may be a part of a rational SRC. A rational SRC may implement a rate conversion “R” with an input rate Fᵢₙ and an output rate Fₒᵤₜ, wherein Fₒᵤₜ may be equal to Fᵢₙ×R. In the SRC 100 the rate conversion R may be expressed as a fraction L/M.

Example FSRC Based on a Polyphase Structure

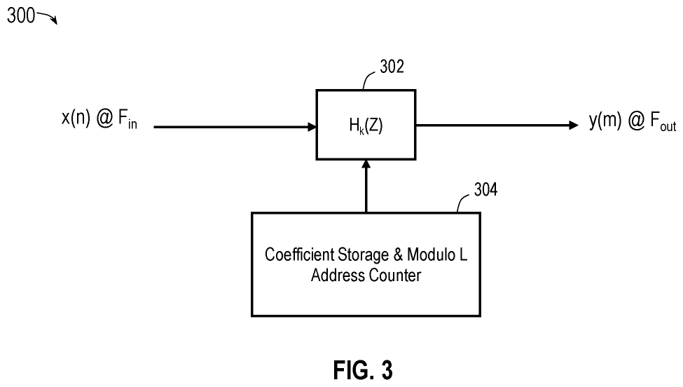

An SRC function, such as performed by the SRC 100 of FIG. 1, may be realized using a polyphase structure. In a polyphase implementation, a signal may be sampled and processed in a number of sub-signals. A polyphase structure may be used to implement a rational SRC in hardware in a computationally efficient manner. FIG. 2 provides a representation of an example SRC 200 that utilizes a polyphase structure (e.g., for downsampling)

In FIG. 2, an input signal x(n) having an input frequency Fᵢₙ (depicted as x(n)@Fᵢₙ) may be input to the rational SRC 200. The input signal may be sampled and processed by a polyphase structure including L sub-filters 202-208 (depicted as H₀(Z)-H_{L-1}(Z)) to perform interpolation by a factor L, where the interpolator output rate is L×Fᵢₙ. The polyphase structure may avoid unnecessary computations with “0s” as may be introduced to the upconverted signal by an interpolator such as interpolator 102 of FIG. 1. The obtained intermediate signal w(p) having an intermediate frequency of L×Fᵢₙ (depicted w(p)@L×Fᵢₙ) may be input to a decimator 210, where M−1 samples from the interpolator may be discarded for every M samples to obtain the output signal y(m) having an output frequency Fₒᵤₜ (depicted as y(m)@Fₒᵤₜ).

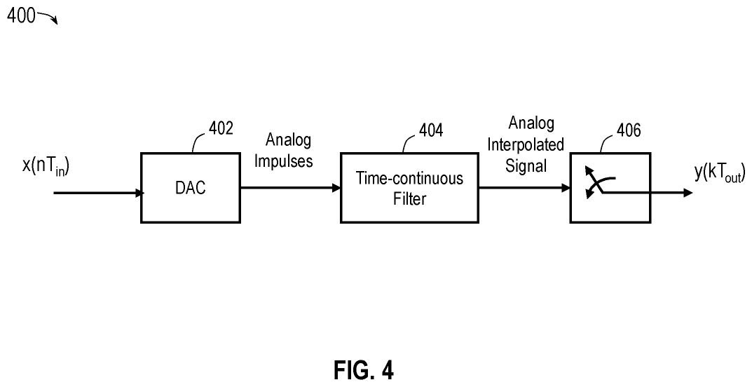

A polyphase implementation, such as the SRC 200 shown in FIG. 2, may be memory inefficient as not all samples stored in the sub-filters are used for obtaining the output signal. In the example of FIG. 2, only one sample out of every M samples from the interpolator is to be computed. Furthermore, in some examples, a rate conversion by rational numbers L/M may be performed, where L and M are integers, e.g., L/M=15625/12289. While the polyphase structure can achieve the exact rate conversion for L/M=15625/12289, a polyphase filter may include 15625 sub-filters. As such, it may be undesirable and inefficient to use a polyphase implementation for such a rate conversion as the memory usage for storing the filter coefficients may be enormous. A more efficient polyphase implementation for sample rate conversion is shown in FIG. 3.

FIG. 3 provides an example implementation of the polyphase structure-based SRC 200 of FIG. 2. Similar to FIG. 2, in FIG. 3, an input signal x(n) having an input frequency Fᵢₙ (depicted as x(n)@Fᵢₙ) may be input to a rational SRC 300 and output of the rational SRC 300 may be an output signal y(m) having an output frequency Fₒᵤₜ (depicted as y(m)@Fₒᵤₜ). The rational SRC 300 may include a polyphase structure with one sub-filter 302 (depicted as Hₖ(Z)) and a memory 304, e.g., a read-only memory (ROM), where coefficients k may be stored. The coefficients k may be indicative of which sample to take from the input signal. For example, if k equals 0, the sub-filter Hₖ(Z) may operate as sub-filter H₀(Z) as shown in FIG. 2. In another example, if k equals 1, the sub-filter Hₖ(Z) may operate as sub-filter H₁(Z) as shown in FIG. 2. The coefficients k may be provided from the memory 304 to the sub-filter 302 at the desired output frequency Fₒᵤₜ (depicted as k@Fₒᵤₜ). Thus, the polyphase structure may avoid unnecessary computations with “0s” and may avoid computing outputs that may be discarded with decimation. Moreover, the filter operating frequency can be Fᵢₙ×L/M instead of Fᵢₙ×L.

In some embodiments, the exact conversion rate may not be known at a design stage of the rate converter, making it difficult or even impossible to choose the number of sub-filters for a polyphase implementation. Consequently, the number of sub-filters in an implementation such as shown in FIG. 2 or the maximum coefficient value k such as shown in FIG. 3 may be difficult to implement.

When implementing an FSRC with a polyphase structure, the following approach may be followed. Choose number of sub-filters as SL (with SL less than L). This allows generating samples with spacing Tᵢₙ/SL. The number SL of stages may determine the granularity of the interpolating process. If Tᵢₙ/SL is sufficiently small so that the successive values of the signal do not change significantly, the value at any location t=n Tᵢₙ+ΔTᵢₙ, 0≤Δ≤1, may be determined using the value of the nearest neighbor (zero-order hold interpolation). In this case the output of one of the sub-filters may be used. Additional improvement may be obtained using two-point linear interpolation. In this output of two adjacent sub-filters of polyphase implementation are used.

With this approach for implementing an FSRC with the polyphase structure, deciding the number of sub-filters (SL) can be difficult and the memory usage for saving the coefficients with a higher SL may be high. Moreover, errors may occur in zero-order hold or linear interpolations.

Improved FSRC Implementation

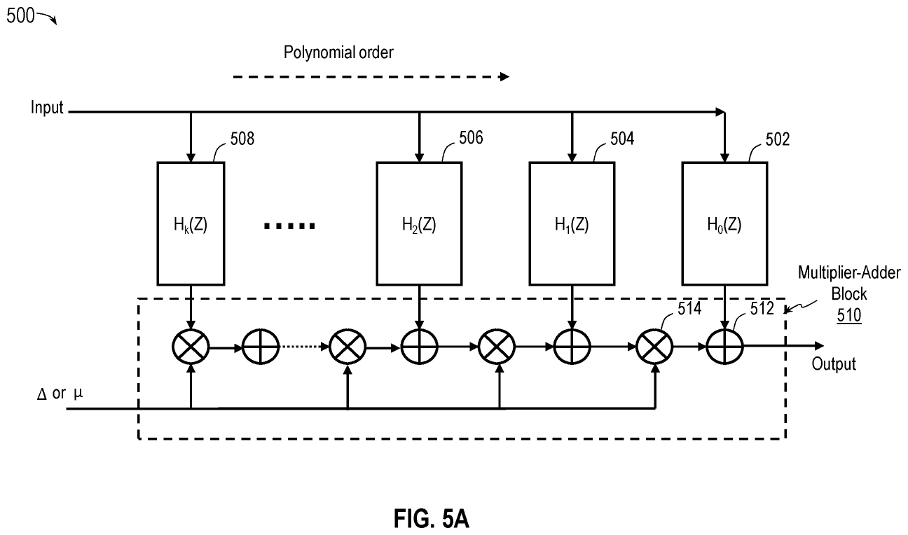

FIG. 4 provides an example FSRC 400 that utilizes a hybrid A/D model. As shown in FIG. 4, a continuous-time signal (or analog interpolated signal) is reconstructed using a digital/analog (D/A)-converter 402 and a time-continuous filter 404 (an anti-imaging filter). The final sample values are then obtained by resampling this continuous-time signal using a sampler 406.

Interpolation filters may be based upon polynomial-based filters, in which the impulse response of the continuous underlying filter is a polynomial. The polynomial may be used to approximate the continuous-time impulse response between the sample points of the input data. Different polynomial coefficients may be used for different sections of the response. FSRC output for the polynomial-based implementation may then be calculated as follows:

y((n+Δ)Tᵢₙ=Σₖ₌₀^{k}Δ^{k}Σᵢ₌₀^{T-1}hₖ⁽ⁱ⁾((n−i)Tᵢₙ)) (1)

wherein K represents the polynomial order, hₖ⁽ⁱ⁾ represents i-th filter coefficients for the filter associated with k-th polynomial order and T represents taps per filter. As can be seen from equation (1), the Δ parameter may represent a fractional sample time interval. In the present disclosure, the Δ parameter, the μ parameter, and “delta value” may be used interchangeably to refer to a fractional sample time interval (e.g., a fractional input sample time interval for interpolation or a fractional output sample time interval for decimation).

Farrow Structure-Based FSRC

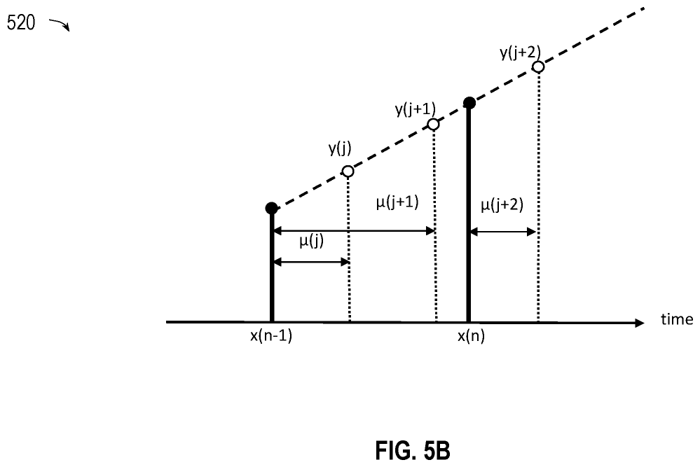

An efficient way of representing polynomial filters is through farrow structures. FIG. 5A provides an example FSRC 500 that utilizes a farrow structure for interpolation. For example, input samples are input to the FSRC 500 at an input rate Fᵢₙ and output data or output samples are output from the FSRC 500 at an output rate Fₒᵤₜ, where Fₒᵤₜ>Fᵢₙ.

As shown in FIG. 5A, the FSRC 500 may include a plurality of filters (shown as 502-508 and depicted as H₀(Z)-Hₖ(Z)). Each of the filters 502-508 may be associated with a different polynomial order k. The filters 502-508 may be arranged sequentially according to respective polynomial orders (shown by the dashed arrow). For example, the filter 508 represented by Hₖ(z) may be associated with the polynomial order k and may operate on x(n) to the power of k. The FSRC 500 may further include a multiplier-adder block 510 including a network of adders and multipliers to combine the outputs of the filters 502-508 in accordance with equation (1). In order not to clutter drawings provided in FIG. 5A, reference numerals are shown for only one multiplier 514 and one adder 512. The multipliers and adders in the multiplier-adder block 510 may be arranged according to a farrow structure (or more generally a polynomial-based structure). The output of each of the filters 502-506 may be coupled to a respective adder and the output of the filter 508 (associated with the highest polynomial order) may be coupled to a respective multiplier.

As can be seen, the arrangement of the filters 502-508 and the multipliers and adders in the multiplier-adder block 510 in FIG. 5 may provide an output represented by: Output=H₀(Z)+μ×H₁(Z)+μ²×H₂(Z)+ . . . μ^{k}×Hₖ(Z).

FIG. 5B is a timing diagram 520 providing an example illustration of the parameter Δ (or μ) used by the FSRC 500 for sample rate conversion. In FIG. 5B, the x-axis represents time in some time units. For simplicity of illustration, FIG. 5B illustrates a linear interpolation but any suitable interpolation techniques may be used. The input samples x(n), x(n−1) (e.g., inputs to the FSRC 500) are shown by the solid-filled circles, where n represents the input sample index. The rate-converted output samples y(j), y(j+1), and y(j+2) (e.g., outputs of the FSRC 500) are shown by the empty circles, where j represents the output sample index. FIG. 5B further illustrates the delta values μ(j), μ(j+1), μ(j+2) for the respective output samples y(j), y(j+1), and y(j+2). Each of the delta values μ(j), μ(j+1), μ(j+2) is a time interval or time distance from one of the input samples x(n−1) or x(n).

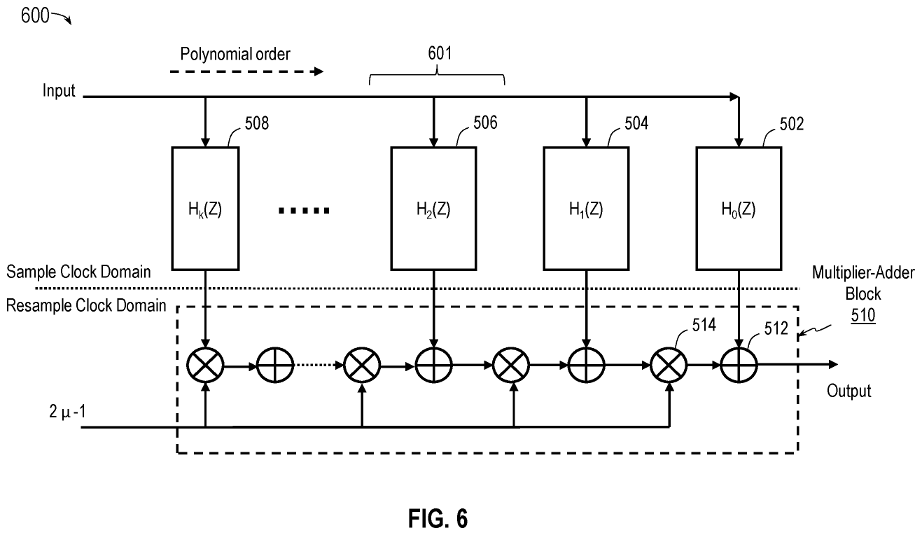

FIG. 6 provides an example FSRC 600 that utilizes a modified farrow structure for interpolation. Input data or input samples x(n) are input to the FSRC 600 at an input rate Fᵢₙ and output data or output samples are output from the FSRC 600 at an output rate Fₒᵤₜ, where Fₒᵤₜ>Fᵢₙ. The FSRC 600 is substantially similar to the FSRC 500. For simplicity's sake, the same reference numerals are used for parts that are the same as the FSRC 500 discussed above. The FSRC 600 differs from the FSRC 500 by the use of 2×μ−1 instead of μ to combine the outputs of the filters 502-508. This modified farrow structure can facilitate the use of symmetric coefficients at the filters 502-508. By using 2×μ−1 instead of μ, the delay control word (the delta values) is now bipolar and ranges from −1 to 1 instead of from 0 to 1.

In an example of a direct farrow implementation for interpolation (e.g., as shown in the FSRC 600 of FIG. 6) where the interpolation rate is R (e.g., R>=1 and Fₒᵤₜ=Fᵢₙ×R), the following parameters may be computed:

accum₀=0,

μᵢ=accumᵢ=mod(accumᵢ₋₁+1/R,1), (2)

ovrᵢ=accum₁≤accumᵢ₋₁, (3)

where μᵢ may represent the delta value for generating the i-th output sample, accumᵢ may represent the modulus accumulation value used for the generation of the delta value μᵢ and may be initialized to 0 for i=0, and ovrᵢ may represent the overflow factor associated with the i-th output sample. As will be discussed further, the overflow factor may signal a new sample request.

For interpolation, the input sampling rate is lower than the output sampling rate. When there is an overflow (ovr in equation (3), e.g., ovr equals 1 or true), a new input may be driven to the filter (e.g., the filters 502-508 in FIG. 6). The sample clock may operate as a gated version of a resample clock and the overflow factor, ovr, may operate as a gating signal. As further shown in FIG. 6, the filters may operate in the sample clock domain (using the gated version of the resample clock) while the multipliers 514 and adders 512 may operate in the resample clock domain (using the ungated resample clock). In an implementation, a lower sampling rate clock may be generated using a higher sampling clock. This may be applicable for both interpolation and decimation.

Table 1 shows an example of delta values (or μ) and associated overflow values for at each output sample processing for a rate change R of 4/3. The delta values and overflow values in Table 1 are generated in accordance with equations (2) and (3) discussed above.

TABLE 1

| i (output sample no.) | accumᵢ (μ) | ovrᵢ | input sample no. |
|---|---|---|---|
| 1 | 0 | 1 | 1 |
| 2 | 0.75 | 0 | 1 |
| 3 | 0.5 | 1 | 2 |
| 4 | 0.25 | 1 | 3 |
| 5 | 0 | 1 | 4 |
| 6 | 0.75 | 0 | 4 |
| 7 | 0.5 | 1 | 5 |
| 8 | 0.25 | 1 | 6 |
| 9 | 0 | 1 | 7 |
| 10 | 0.75 | 0 | 7 |
| 11 | 0.5 | 1 | 8 |
| 12 | 0.25 | 1 | 9 |

In the example of table 1, input samples (received at the input of the FSRC 600) may be fed to filters (e.g., the filters 502-508) and each filter (e.g., H₀(Z) to Hₖ(Z)) output may be multiplied by a power of (2×μ−1) from 0 to k (e.g., (2×μ−1)\hat{ }k), respectively, and then added together as shown in FIG. 6. The input sample no. in table 1 may refer to output samples from a respective filter 502-508 that are input into the multiplier-adder block 510. The output sample no. in table 1 may refer to output samples at the output of the FSRC 600 as generated by the multiplier-adder block 510. As can be observed from Table 1, the delta values generated from equation (2) may each correspond to a time interval or a time distance (e.g., a fraction of an input sample interval, 1/ᵢₙ) from one of the received input samples.

For simplicity discussion, the followings are described for operations for one of the k polynomial sections, for example, for the section 601 associated with a polynomial order of 2 (e.g., along the path of H₂(Z)) shown in FIG. 6. More specifically, the operations are for transferring samples from the filter H₂(Z) to a respective adder in the multiplier-adder block 510. Similar operations may be performed for each of the k polynomial sections or filter paths. In the illustrated example of Table 1, for input sample 1, using the filter output at that time, output samples 1 and 2 are generated by using delta (μ) as 0 and 0.75, respectively. This indicates, for one input sample coming in, multiple output samples are generated for interpolation. When the next input sample (sample 2) feeds the filter, output sample 3 is generated. This process may be continued for all input samples in table 1.

Decimation may be performed using similar techniques (e.g., equations (2)-(3)) discussed above for interpolation. In decimation, the input sampling rate is higher than the output rate. For example, the input rate is Fᵢₙ and the output rate is Fₒᵤₜ, where Fₒᵤₜ=Fᵢₙ/R and R>1. For decimation, the input data may be multiplied by a power of (2×μ−1) from 0 to k (e.g., (2×μ−1)\hat{ }k). When there is no overflow (e.g., ovr equals zero or false), the multiplied data may be integrated (or added). When there is an overflow (e.g., ovr equals 1 or true), the integrated data may be dumped (or output) to a respective filter and the respective integrator may be reset. The resample (output) clock may be used as a gated version of the sample (input) clock and ovr may be used as a gating signal.

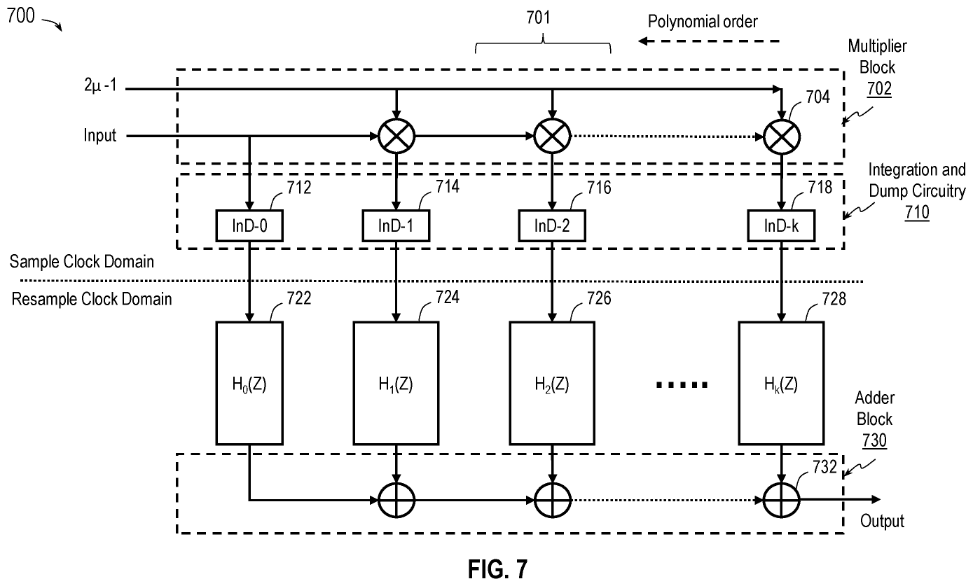

FIG. 7 provides an example FSRC 700 that utilizes a modified farrow structure for decimation. For example, input data or input samples x(n) are input to the FSRC 700 at an input rate Fᵢₙ and output data or output samples are output from the FSRC 700 at an output rate Fₒᵤₜ<Fᵢₙ (e.g., Fₒᵤₜ=Fᵢₙ/R, where R is greater than 1).

As shown in FIG. 7, the FSRC 700 may include a multiplier block 702, integration and dump circuitry 710, a plurality of filters (shown as 722-728 and depicted as H₀(Z)-Hₖ(Z)), and an adder block 730. Each of the filters 722-728 may be associated with a different polynomial order k. The filters 722-728 are arranged sequentially according to respective polynomial orders (shown by the dashed arrow). For example, the filter 728 represented by Hₖ (z) may be associated with the polynomial order. The multiplier block 702 may include a network of multipliers, and the adder block 730 may include a network of adders. In order not to clutter drawings provided in FIG. 7, reference numerals are shown for only one multiplier 704 in the multiplier block 702 and one adder 732 in the adder block 730. The multipliers in the multiplier block 702 and the adders in the adder block 730 may be arranged according to a farrow structure (or more generally a polynomial-based structure). As further shown, the multiplier block 702 and the integration and dump circuitry 710 may operate in a sample clock domain while the filters 722-728 and the adder block 730 may operate in a resample clock domain. In contrast to interpolation, the sample clock for the FSRC 700 may be the input clock and the resample clock for the FSRC 700 may be the gated version of the sample clock.

The integration and dump circuitry 710 may include a plurality of integration and dump sub-circuitries (shown as 712-718 and depicted as InD-0 to InD-k) coupled to respective ones of the plurality of filters 722-728. For each input sample x(n), 2×μ−1 may be multiplied recursively using the multipliers 704 to provide (2×μ−1)\hat{ }k for k varying from 1 to K. In other words, each input sample may be multiplied by (2×μ−1)\hat{ }k for k varying from 1 to K and the multiplied data may be provided to respective integration and dump sub-circuitries 714-718. The integration and dump sub-circuitry 712 (InD-0) coupled to the filter 722 H₀(k) associated with the 0-th polynomial order may receive the input sample directly.

At each integration and dump sub-circuitry 712, 714, 716, and 718, when there is no overflow (e.g., ovr equals zero or false), inputs to the respective integration and dump sub-circuitry 712, 714, 716, and 718 may be integrated (or added). For instance, each integration and dump sub-circuitry may have a storage or memory to store an integrated data (e.g., represented by InD-k data). When there is an overflow (e.g., ovr equals 1 or true in equation (3)), the integrated data may be dumped (output) to the respective filter 722, 724, 726, and 728 and the respective integrator may be reset. The filters 722-728 may filter samples output by respective integration and dump sub-circuitries 712-718. The adders 732 may combine the output from each of the of the filters 722-728 to generate rate-converted samples at the output of the FSRC 700.

Table 2 shows an example of delta (or μ) and overflow values at each input sample processing for a rate change R of 4/3. The delta values and overflow values in Table 2 are generated in accordance with equations (2) and (3) discussed above. However, for decimation, μᵢ in equation (2) may represent the delta value for generating the i-th input sample rather than the i-th output sample and ovrᵢ may represent the overflow factor may be associated with the i-th input sample (to the filters 712-718). Further, the overflow factor may signal a new sample write request (to the filters 712-718). As can be observed from Table 2 below, the delta values generated from equation (2) may each correspond to a time interval or a time distance (e.g., a fraction of an output sampling time interval, 1/Fₒᵤₜ) from one of the output samples.

TABLE 2

| i (input sample no.) | accumᵢ (μ) | ovrᵢ | output sample no. |
|---|---|---|---|
| 1 | 0 | 1 | 1 |
| 2 | 0.75 | 0 | 1 |
| 3 | 0.5 | 1 | 2 |
| 4 | 0.25 | 1 | 3 |
| 5 | 0 | 1 | 4 |
| 6 | 0.75 | 0 | 4 |
| 7 | 0.5 | 1 | 5 |
| 8 | 0.25 | 1 | 6 |
| 9 | 0 | 1 | 7 |
| 10 | 0.75 | 0 | 7 |
| 11 | 0.5 | 1 | 8 |
| 12 | 0.25 | 1 | 9 |

In the example of table 2, an input sample (received at the input of the FSRC 700) may be multiplied by a power of (2×μ−1) from 0 to k e.g., (2×μ−1)\hat{ }k), and fed to the integration and dump sub-circuitries 712-718 (e.g., InD-0 to InD-k), respectively, as shown in FIG. 7.

For simplicity discussion, the followings are described for operations for one of the k polynomial sections, for example, for the section 701 associated with a polynomial order of 2 (e.g., along the path of H₂(Z)) shown in FIG. 7. More specifically, the operations are for transferring samples from the integration and dump sub-circuitry 716, InD-2, to the filter H₂(Z). Similar operations may be performed for each of the k polynomial sections or filter paths. In the illustrated example of Table 2, for input sample 1, delta(μ)=0 and ovr=1. After multiplication with a power of (2×μ−1), the multiplied data may be fed to a respective InD-k and added to the previous InD-k data (e.g., the integrated data at the InD-k). Because ovr=1, the added data may be sent to a respective filter and the InD data may be reset to zero.

For input sample 2, delta(μ)=0.75 and ovr=0. After multiplication with a power of (2×μ−1), the multiplied data may be fed to a respective InD-k and added to the previous InD-k data (e.g., which may equal to zero due to the reset). Because ovr=0, the InD-k data may not be sent out of InD-k. That is, the InD-k data is retained at the integration and dump sub-circuitry. This means that the data at the input of the respective filters may not change and the filter may not be clocked for that cycle.

For input sample 3, delta(μ)=0.5 and ovr=1. After multiplication with a power of (2×μ−1), the multiplied data may be fed to InD-k and added to the previous InD-k data (sample 2). Because ovr=1, the InD-k data (added data) may be sent to the filter and the InD-k data is reset to zero.

Stated differently, the integration and dump operation at each integration and dump sub-circuitry 712, 714, 716, 718 may include receiving an input (e.g., multiplied data), adding the input to an accumulator (internal or local to the respective integration and dump sub-circuitry) to generate a new integrated value, storing the new integrated value at an internal memory, and outputting the new integrated value and resetting the accumulator (and/or memory) if ovr is true. This process may be continued for all input samples in table 2.

Example Generation of Delta (μ) Values Through Accumulations

In an embodiment, an accumulator-based approach may be used to calculate delta values (μᵢ in equation (2)) and overflow values (ovrᵢ in equation (3)) at a higher sampling clock (at a sampling frequency of Fs). That is, the sampling clock may correspond to the output clock (Fₒᵤₜ) for interpolation or to the input clock (Fᵢₙ) for decimation. The following parameters may facilitate the generation of delta values (μ) using the accumulation techniques discussed above with reference to equations (2)-(3):

$$R = \frac{L}{M} ,$$

where R is a rate change value (which may be a fractional value) greater than or equal to 1,

R_int=(floor(M/L*2\hat{ }Pbits)), where P is the accumulator bit-width (e.g., 48 bits),

R_frac_A=mod(2\hat{ }Pbits*M,L), where mod is a modulo operation, and

R_frac_B=L.

Thus, 1/R=(R_int+R_frac_A/R_frac_B)/2\hat{ }Pbits.

The following equations show an example integer (or fixed-point) implementation of intermediate values for generating of delta values (e.g., represented by μᵢ, or Deltaᵢ, where i represents an output sample number in the case of interpolation or an input sample number in the case of decimation) using the modules accumulation techniques:

int_accumᵢ=mod (int_accumᵢ₋₁+R_int,2\hat{ }Pbits), (4)

mod_valueᵢ=mod (mod_valueᵢ₋₁+R_frac_A,R_frac_B), (5)

mod_incrᵢ=(mod_valueᵢ₋₁+R_frac_A)≥R_frac_B for R_frac_A>0 or equals “0” for R_frac_A=0, (6)

mod_accumᵢ=mod (mod_accumᵢ₋₁+mod_incrᵢ,2\hat{ }Pbits). (7)

In one embodiment, a further intermediate value may be computed as follows:

accumᵢ=mod (int_accumᵢ+mod_accumᵢ,2\hat{ }Pbits), (8)

and delta values may be computed as follows:

Deltaᵢ=accumᵢ[Pbits−1:Pbits−D]; D is delta bit-width. (9)

In another embodiment, the intermediate value accumᵢ may be computed as follows:

accumᵢ=mod (accumᵢ₋₁+R_int+mod_incrᵢ₋₁,2\hat{ }Pbits), (10)

and the delta values may be computed using equation (9).

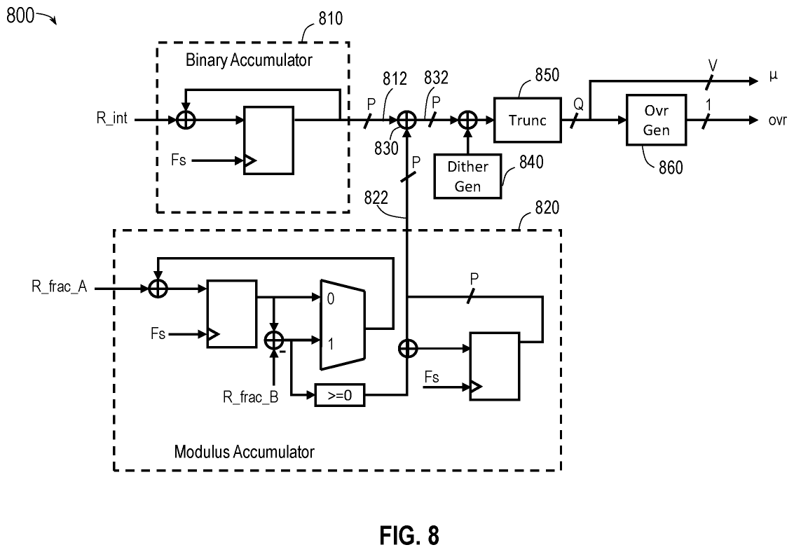

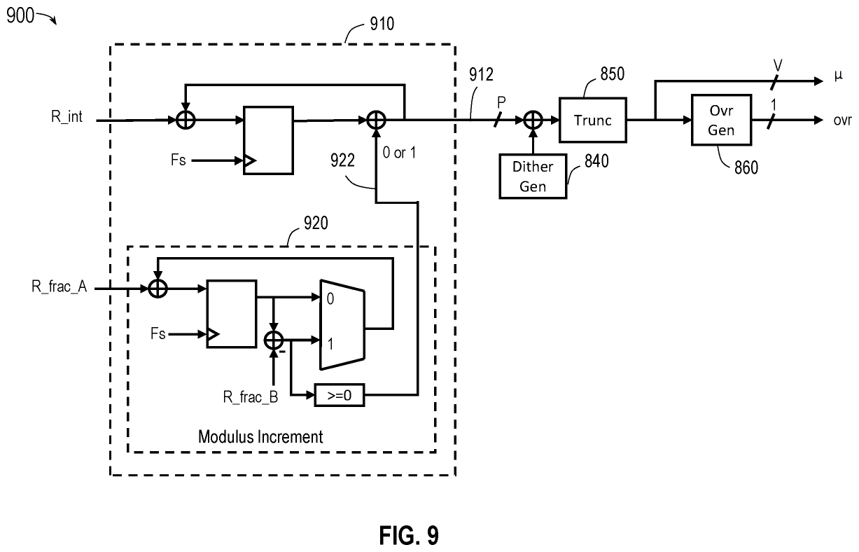

FIGS. 8-9 illustrate exemplary digital hardware implementations for delta value generation using equations (4) to (10). FIG. 8 provides an example digital hardware implementation for an accumulator 800 that generates delta values for a farrow structure-based SRC, according to some embodiments of the present disclosure. The accumulator 800 may generate delta and overflow values in accordance with equations (4)-(9). FIG. 9 provides an example digital hardware implementation for an accumulator 900 that generates delta values for a farrow structure-based SRC, according to some embodiments of the present disclosure. The accumulator 900 may generate delta and overflow values in accordance with equations (4)-(7) and (9)-(10). The accumulators 800 and 900 may be used for interpolation and/or decimation. For instance, while not shown, each of the FSRC 500 of FIG. 5, FSRC 600 of FIG. 6, or the FSRC 700 of FIG. 7 may include an accumulator as shown in FIG. 8 or FIG. 9 for computing delta values and overflow values that are used for sample rate conversion as discussed above.

Referring to FIG. 8, the accumulator 800 may include a binary accumulator 810, a modulus accumulator 820, an adder 830, a dither generator 840, a truncator 850, and an overflow generator 860. The binary accumulator 810 may compute a P-bit value 812 (an integer value) in accordance with equation (4), where the value 812 may correspond to int_accumᵢ. The modulus accumulator 820 may compute a P-bit value 822 in accordance with equations (5)-(7), where the value 822 may correspond to mod_accumᵢ. As shown, R_int may be used for binary accumulation at the binary accumulator 810 and R_frac_A, R_frac_B may be used for modulus accumulation at the modulus accumulator 820. The adder 830 may add int_accumᵢ and mod_accumᵢ to provide a P-bit value 832 in accordance with equation (8), where the value 832 may correspond to accumᵢ.

Referring to FIG. 9, the accumulator 900 may be substantially similar to the accumulator 800 but may include an accumulator 910 that computes accumᵢ in accordance with equation (10) instead of equation (8). The accumulator 910 may include a modulus increment generator 920. The modulus increment generator 920 may compute a modulus increment value 922, which may be 0 or 1, in accordance with equation (6), where the value 922 may correspond to mod_incrᵢ. The accumulator 900 may also include a dither generator 840, a truncator 850, and an overflow generator 860 similar to the accumulator 810 of FIG. 8.

As further shown in FIG. 8, the binary accumulator 810 and the modulus accumulator 820 may include flip-flops clocked by a sampling rate clock Fs. Similarly, as further shown in FIG. 9, the accumulator 910 may include flip-flops clocked by a sampling rate clock Fs. The Fs in the accumulator 800 of FIG. 8 and in the accumulator 900 of FIG. 9 may be the high sampling rate clock between the input sampling clock and the output sampling as discussed above. For example, the sampling clock Fs may correspond to the output resampling clock for interpolation and may correspond to the input sampling clock for decimation. The high sampling rate clock may be used to generate the delta (μ or Δ) and overflow (ovr).

As further shown in FIGS. 8 and 9, the accumulators 800 and 900 may use P bits to represent R_int, R_frac_A, R_frac_B and V bits to represent delta values (μ or Δ). Accordingly, the truncation generator 850 (shown as trunc) may truncate accumᵢ (e.g., the accumulated value 832 in FIG. 8 or the accumulated value 912 in FIG. 9) from P bits to V bits. In an example, P may be 48 and V may be 16 (e.g., delta may be taken from accumᵢ [47:32]). However, the accumulators 800 or 900 in accordance with FIG. 8 or 9, respectively, are not limited to these number of bits and any other suitable number of bits may be used.

As further shown in FIGS. 8 and 9, a dither may be generated by the dither generator 840 and added to accumᵢ (e.g., the accumulated value 832 in FIG. 8 or the accumulated value 912 in FIG. 9) to reduce the spurs from the truncation (e.g., by the truncation generator 850) for generating delta (μ or Δ).

As further shown in FIGS. 8 and 9, the overflow generator 860 may compute an overflow value (depicted as ovr) by comparing accumᵢ for a current sample to accumᵢ₋₁ for a previous sample in accordance with equation (2) above.

In general, delta (μ) and ovr generation may have the same operations (e.g., computations of equations (4)-(10)) for interpolation and decimation. However, for interpolation, delta values (μ or in modified farrow 2×μ−1) may be used to multiply the filter output (e.g., outputs of the filters 502-508 shown in FIGS. 5 and 6) and overflow values may be used to request for a new output sample from a respective filter. For decimation, delta values (μ or in modified farrow 2×μ−1) may be used to multiply the input data (e.g., FSRC input samples x(n)) and overflow values may be used to dump or output integrated data, which are to be used as filter inputs (e.g., inputs of the filters 722-728 shown in FIG. 7).

To facilitate the discussion for the parallel implementation scheme, the following definitions will be used When the sample rates are very high (e.g., in the MHz range or GHz range), operating the digital logic (e.g., the accumulators 800 and 900 shown in FIGS. 8 and 9, respectively) at a high Fs clock may not be possible.

Example FSRC at Higher Sampling Rates

According to aspects of the present disclosure, for FSRC at a high sample rate, accumulators for generating delta values and overflow values for sample rate conversion may be operated at a slow rate, for example, at a Fs/N frequency, where Fs the sampling clock frequency (which may correspond to the output sampling clock in the case of interpolation or the input sampling clock in the case of decimation) and N may be any integer value greater than 1. In some examples, N may be a power of 2. Accordingly, the FSRC may be operated with “N” parallel samples processed per clock cycle in filters and delta generations. In some instances, N may be referred to as a clock division value.

To facilitate the discussion for the parallel implementation scheme, the following definitions may be used:

Fsh: Higher sampling rate clock, which may correspond to the output resampling rate clock in interpolation or the input sampling rate clock in decimation

Fsl: Lower sampling rate clock, which may correspond to the input sampling rate clock in interpolation or the output resampling rate clock in decimation.

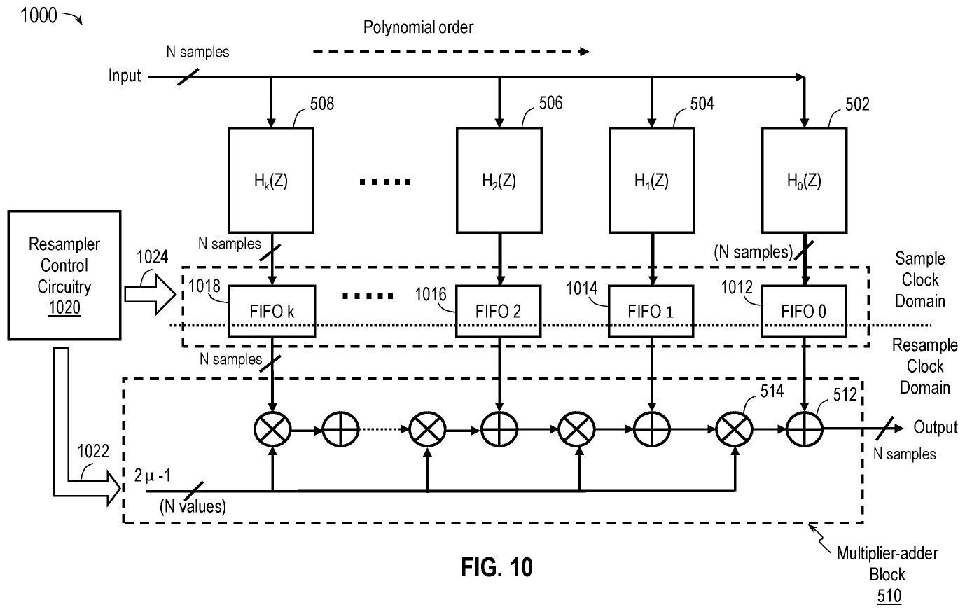

FIG. 10 provides an example farrow structure-based FSRC 1000 with a parallel structure for interpolation, according to some embodiments of the present disclosure. The FSRC 1000 of FIG. 10 shares many elements with the FSRC 600 of FIG. 6; for brevity, a discussion of these elements is not repeated, and these elements may take the form of any of the embodiments disclosed herein. However, the FSRC 1000 may utilize a parallel architecture to facilitate interpolation at high sampling rates (e.g., in the GHz range).

As shown in FIG. 10, the FSRC 1000 may include a plurality of filters (shown as 502-508), a plurality of FIFOs (shown as 1012-1018 and depicted as FIFO 0 to FIFO k), and a multiplier-adder block 510. Each FIFO 1012-1018 may be coupled to the output of a respective one of the plurality of filters 502-508. For example, the FIFO 1012 (FIFO 0) is coupled to the output of the filter 502, the FIFO 1014 (FIFO 1) is coupled to the output of the filter 504, and so on. Further, the output of each of the FIFOs 1012-1016 may be coupled to a respective adder and the output of the FIFO 1018 (associated with the highest polynomial order filter 508) may be coupled to a respective multiplier. The FSRC 1000 may operate at a clock rate of Fs/N but may operate on N samples in each clock cycle. That is, the FSRC 1000 may receive input samples at a rate of Fin and output rate-converted samples at a rate Fₒᵤₜ=Fᵢₙ×R, where R is a rate change factor greater than 1, but the digital hardware logics or circuitries may operate at Fs/N, where Fs may correspond to Fₒᵤₜ (the higher of Fᵢₙ and Fₒᵤₜ). Accordingly, the FSRC 1000 may include N instances of the filters 502-508 to produce N samples at the output of each of the filters 502-508 in one clock cycle. The FSRC 1000 may further include N instances of the multiplier-adder block 510 to produce N output samples in one clock cycle.

As can be seen, the FSRC 1000 of FIG. 10 differs from the FSRC 600 of FIG. 6 not only in operating with N samples but also in using FIFOs (e.g., the FIFOs 1012-1018) to transfer data from an input sample clock domain (Fsl/N) to an output resample clock domain (Fsh/N). Each FIFO may be connected to the output of one of the filter transfer data from the filter to a respective multiplier or adder to generate an output sample. In other words, each FIFO of the plurality of FIFOs 1012-1218 may store output samples of a respective one of the plurality of filters 502-508, and the stored samples may be read from each FIFO based on N FIFO read pointers (e.g., represented by fifo_rd_ptr[X] for X varying from 0 to N−1). The calculation of the N FIFO read pointers will be discussed more fully below.

For each clock cycle, N samples may be processed. As such, the operating clocks are divided by N. Each multiplier (e.g., the multiplier 514) in the multiplier-adder block 510 may perform N multiplications for the N samples read from the FIFO read data in each cycle (e.g., multiplying by a corresponding 2×μ−1). The operating clock can be generated using two options. In a first option, an Fsh/N clock can be generated from Fsh with a divider value N. In a second option, an Fsh/N clock can be generated from Fsh/N1 with a divider value N2, here N1×N2=N. In some examples, it may be desirable to use the second option when Fs is high compared to the speed of the digital cells to reduce the physical implementation (timing) challenges in operating the divider at higher frequencies.

Similarly, Fsl/N generation may be performed using various approaches. For example, a first approach may utilize the Fsh clock to generate ovr in accordance with equation (3) (e.g., as show in FIG. 8 or FIG. 9) and utilize ovr to gate the Fsh clock, and divide the gated Fsh by N. Here, the“gated Fsh” frequency may be equivalent to Fsl. A second approach may utilize the Fsh/N1 clock to generate ovr in accordance with equation (3) and utilize ovr to gate the Fsh/N1 clock, and divide the “gated Fsh/N1” by N2. Here, N=N1×N2. A third approach may utilize an Fsh/N clock to generate ovr in accordance with equation (3) and utilize ovr to gate the Fsh/N clock. The “gated Fsh/N” may be equivalent to Fsl/N. The ratio between the frequency of the Fsh/N clock to the Fsl/N clock may be the rate change (R). In the following discussions, “ungated Fsh/N” is denoted as Fsh/N and “gated Fsh/N” is denoted as Fsl/N.

As will be discussed more fully below, the FSRC 1000 may further include resampler control circuitry 1020 to generate delta values (shown by the arrow 1022) and FIFO read and/or write pointers (shown by the arrow 1024) for transferring samples from the filters 502-508 to respective FIFOs 1012-1018. To perform sample rate conversion at high sampling rates, parameters N, X, FIFO_DEPTH may be defined to assist the computation of delta values and determination on how to use the input samples to generate output samples (e.g., via FIFO read pointers and FIFO write pointers).

For a rate change R (>1), N may represent the number of samples processed per operating clock (Fsh/N or Fsl/N), X may represent a sample index varying from 0 to N−1, and FIFO_DEPTH may represent the size of each of the FIFOs 1012-1018 can be dependent on a particular hardware design. As an example, the FIFO_DEPTH can be 4N. To relax the timing requirement between the input and output clocks through FIFO 1012-1018, the FIFO_DEPTH can be an increased integer multiple of N (>4N).

Delta may represent μ (the fractional sample time interval in farrow structures). For the multiplication, 2×μ−1 may be used in a modified farrow structure as discussed above.

To facilitate generation of N delta values and N FIFO read/write pointers in each cycle, a set of parameters including a base accumulation value, an intermediate accumulation, a delta value, a FIFO pointer increment, a FIFO pointer offset, a FIFO base pointer, a FIFO read pointer, and a FIFO write pointer represented by base_accumᵢ, accumᵢ[X], deltaᵢ[X], fifo_ptr_incrᵢ₋₁, fifo_ptr_addᵢ[X], fifo_base_ptrᵢ, fifo_rd_ptrᵢ[X], and fifo_wr_ptrᵢ[X], respectively, may be defined as discussed below. For example, base accumulation values may be computed as shown below:

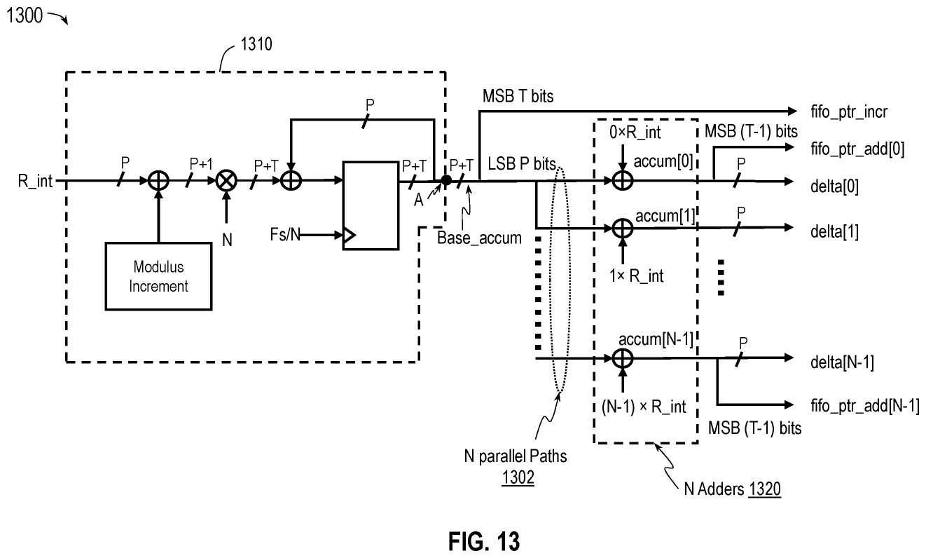

base_accumᵢ=mod (base_accumᵢ₋₁,1)+N×1/R, (11)

where i may represent the output clock cycle number for the FSRC 1000. The base_accumᵢ may be computed once for every block of N input samples. In an aspect, the resampler control circuitry 1020 may include a modulus accumulator (e.g., the base accumulator 1310 shown in FIG. 13) that operates off of the Fsh/N clock for calculating base_accumᵢ.

Intermediate accumulation values may be computed as shown below:

accum_{i[X}]=mod (base_accumi,1)+(X)×1/R. (12)

In equation (12), X=0,1 . . . N−1 and 0<accumᵢ[X]<N+1. In other words, N accumᵢ[X] may be computed for every block of N input samples. In an aspect, to avoid having to multiply X by 1/R in the calculation of accumᵢ[X], the resampler control circuitry 1020 may include N parallel paths coupled to the output of the base accumulator and may include N−1 adders (e.g., the N adders 1320 shown in FIG. 13) to add an additional offset into each path.

Delta values may be computed as shown below:

delta_{i[X}]=mod (accum_{i[X}],1). (13)

In equation (13), X=0,1 . . . N−1. That is, a delta value is calculated for each parallel path (e.g., as shown in FIG. 13) and N delta values may be computed for every block of N input samples.

Increments for incrementing a FIFO base pointer may be computed as shown below:

fifo_ptr_incrᵢ₋₁=floor(base_accumᵢ). (14)

That is, fifo_ptr_incrᵢ₋₁ may correspond to the integer part of base_accumᵢ and may be computed once for every block of N input samples.

Offsets for adding to a FIFO base pointer may be computed as shown below:

fifo_ptr_add_{i[X}]=floor(accum_{i[X}]). (15)

In equation (15), the term floor(accumᵢ[X]) may correspond to the integer part of accumᵢ and X=0,1 . . . N−1. Thus, N fifo_ptr_addᵢ may be computed for each block of N input samples. However, in some instances, consecutive fifo_ptr_addᵢ can have the same in these N values, where 0≤fifo_ptr_addᵢ≤N.

The FIFO base pointer may be pointing to a reference or starting FIFO location for a block of N samples in a clock cycle of the Fsh/N clock and may be computed as shown below:

fifo_base_ptrᵢ=mod(fifo_base_ptrᵢ₋₁+fifo_ptr_incrᵢ₋₁,FIFO_DEPTH). (16)

The FIFO read pointers may each be pointing to a FIFO location for reading and may be computed as shown below:

fifo_rd_ptr_{i[X}]=mod(fifo_base_ptrᵢ+fifo_ptr_add_{i[X}],FIFO DEPTH). (17)

In equations (16) and (17), X=0,1 . . . N−1. Thus, N fifo_base_ptrᵢ and fifo_rd_ptrᵢ[X] may be computed for every block of N input samples.

The computation of the parameters base_accumᵢ, accumᵢ[X], deltaᵢ[X], fifo_ptr_incrᵢ₋₁, fifo_ptr_addᵢ[X], fifo_base_ptrᵢ, and fifo_rd_ptrᵢ[X] discussed above in equations (11)-(17) may be performed at Fsh/N clock.

On the other hand, the computation of FIFO write pointers (e.g., fifo_wr_ptr) may be performed at Fsl/N clock, for example, as shown below:

wrptrᵢ=mod(wrptrᵢ₋₁+1,FIFO_DEPTH/N). (18)

A FIFO write pointer, represented by fifo_wr_ptrᵢ[X], may each be pointed to a FIFO location for writing and can be computed as shown below in equation (19) or (2):

fifo_wr_ptr_{i[X}]=mod(fifo_wr_ptr_{i-1[N-}1]+1+X,FIFO_DEPTH). (19)

fifo_wr_ptr_{i[X}]=wrptrᵢ×N+X. (20)

In interpolation, write to the FIFO is preferably N sample in Fsl/N clock domain. Based on R and the specific time, by using the single FIFO sample, multiple consecutive output samples may be generated with different delta values.

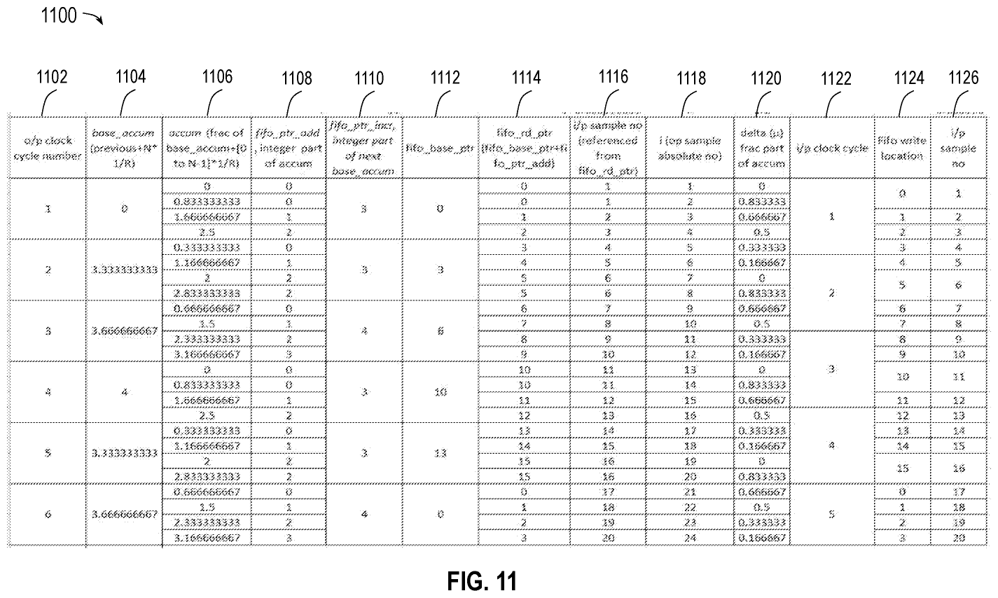

FIG. 11 is a table 1100 of example parameters that facilitate sample rate conversion, according to some embodiments of the present disclosure. The table 1100 provides values for the above parameters base_accumᵢ (shown in column 1104), accumᵢ[X] (shown in column 1106), deltaᵢ[X] (shown in column 1120), fifo_ptr_incrᵢ₋₁ (shown in column 1110), fifo_ptr_addᵢ[X] (shown in column 1108), fifo_base_ptrᵢ (shown in column 1112), fifo_rd_ptrᵢ[X] (shown in column 1114), and fifo_wr_ptrᵢ[X] (shown in column 1124) computed in corresponding input clock cycles (shown in column 1112) and/or corresponding output clock cycles (shown in column 1102) as discussed above. The values in the table 1100 are generated with N=4, FIFO_DEPTH=16, and R=1.2 (=6/5) and in accordance with respective equations for those parameters. In an aspect, the values shown in Table 1100 may be applied to each filter/FIFO branch shown in FIG. 10.

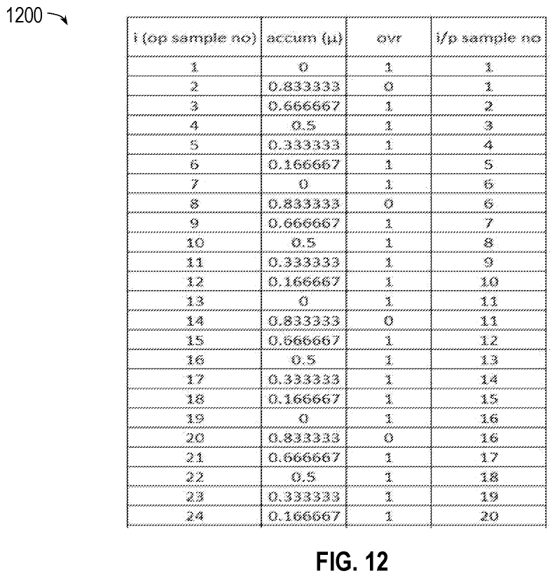

FIG. 12 is a table 1200 of example parameters that facilitate sample rate conversion, according to some embodiments of the present disclosure. The table 1200 provides values for delta values and ovr. The values in table 1200 are generated with N=1, e.g., using the accumulators 800 or 900 shown in FIG. 8 or 9, respectively. For the corresponding output data sample, the input (filter data output) and delta may be the same in tables 1100 and 1200.

To generate values shown in the table 1100 of FIG. 11, starting values for base_accum, fifo_base_ptr and wrptr, fifo_wr_ptr may be initialize or set to zero. In some examples, these parameters may be separately initialized (e.g., to different values) to ease timing between FIFO write clock (Fsl/N) and read clock (Fsh/N). In the example with N=4 illustrated in the table 1100, for each input clock cycle (Fsl/4), 4 input samples (filtered data output) are written to each FIFO 1012-1018 and 4 samples are read from each FIFO 1012-1018. As can be seen from the table 1100, multiple reads can correspond to the same data depending on R and the particular time instances.

Referring to the table 1100, in input cycle 1, wrptr=0 (fifo_wr_ptr[0]=0), fifo_wr_ptr[0 to 3]=0 to 3, so 4 input samples are written into FIFO location 0 to 3. In input cycle 2, wrptr=1 and fifo_wr_ptr[0 to 3]=4 to 7, 4 input samples of this cycle are written into FIFO location 4 to 7. In input cycle 3, wrptr=2, so 4 input samples of this cycles are written into FIFO location 8 to 11. In input cycle 4, wrptr=3, so 4 input samples of this cycles are written into FIFO location 12 to 15. In input cycle 5, wrptr=0, so 4 input samples of this cycles are written into FIFO location 0 to 3. The last three columns (columns 1122, 1124, and 1126) of table 1100 indicate the FIFO writing information.

The following value for 1/R may be used: 1/R=5/6=0.8333.

In output clock cycle 1 (i=1), output samples 1 to 4:
base_accum₁=0, accum₁[X]=mod (base_accum₁,1)+(X)×1/R=(0 to 3)×0.8333 . . . =0, 0.8333 . . . , 1.666 . . . , 2.5; delta₁=mod (accum₁[X],1)=0, 0.8333 . . . , 0.666 . . . , 0.5. base_accum₂=mod(base_accum₁,1)+N×1/R=4×1/R=0+3.3333 . . . , fifo_ptr_incr₁=floor(base_accum₂)=3
fifo_base_ptr₁=0, fifo_ptr_add₁=floor(accum₁[X])=0,0,1,2; fifo_rd_ptr₁[X]=mod(fifo_base_ptr₁+fifo_ptr_add₁[X], FIFO DEPTH)=0,0,1,2. Four output samples are generated by using the data from FIFO locations 0,0,1,2 with corresponding delta(μ)=0, 0.8333 . . . , 0.666 . . . , 0.5. Input samples 1,1,2,3 are in FIFO locations 0,0,1,2

In output clock cycle 2, i=2, output samples 5 to 8:
base_accum₂=3.3333 . . . , accum₂ [X]=mod (base_accum₂,1)+(X)×1/R=0.333 . . . +(0 to 3)×0.8333 . . . =0.333 . . . , 1.1666 . . . , 2.0, 2.8333 . . . ; delta₂=mod (accum₂ [X],1)=0.333 . . . , 0.1666 . . . , 0, 0.8333 . . . base_accum₃=mod(base_accum₂,1)+N×1/R=0.333 . . . +4×1/R=3.666 . . . , fifo_ptr_incr₂=floor(base_accum₃)=3
fifo_base_ptr₂=mod(fifo_base_ptrᵢ₋₁+fifo_ptr_incrᵢ₋₁, FIFO_DEPTH)=3, fifo_ptr_add₂=floor(accum₂[X])=0,1,2,2; fifo_rd_ptr₂[X]=mod(fifo_base_ptr₂+fifo_ptr_add₂[X], FIFO DEPTH)=3,4,5,5. Four output samples are generated by using the data from FIFO locations 3,4,5,5 with corresponding delta(u)=0.333 . . . , 0.1666 . . . , 0, 0.8333 . . . .

In output clock cycle 3, i=3, output samples 9 to 12:
base_accumᵢ=3.666 . . . , accumᵢ[X]=mod (base_accum_{i,1})+(X)×1/R=0.666 . . . +(0 to 3)×0.8333=0.666 . . . , 1.5, 2.333 . . . , 3.1666 . . . ; deltaᵢ=mod (accumᵢ[X],1)=0.666 . . . , 0.5, 0.333 . . . , 0.1666 . . . base_accumᵢ₋₁=mod(base_accumᵢ,1)+N×1/R=0.666 . . . +4×1/R=4, fifo_ptr_incrᵢ=floor(base_accumᵢ₊₁)=4
fifo_base_ptrᵢ=mod(fifo_base_ptrᵢ₋₁+fifo_ptr_incrᵢ₋₁, FIFO_DEPTH)=3+3=6, fifo_ptr_add₂=floor(accum₂[X])=0,1,2,3; fifo_rd_ptr₂[X]=mod(fifo_base_ptr₂+fifo_ptr_add₂[X], FIFO DEPTH)=6,7,8,9. Four output samples are generated by using the data from FIFO locations 6,7,8,9 with corresponding delta(μ)=0.666 . . . , 0.5, 0.333 . . . , 0.1666 . . . .

In output clock cycle 4, i=4, output samples 13 to 16:
base_accumᵢ=4, accumᵢ[X]=mod (base_accumᵢ,1)+(X)×1/R=0+(0 to 3)×0.8333=0, 0.8333 . . . , 1.666 . . . , 2.5; deltaᵢ=mod (accumᵢ[X],1)=0, 0.8333 . . . , 0.666 . . . , 0.5. base_accumᵢ₊₁=mod(base_accumᵢ,1)+N×1/R=0+3.3333 . . . , fifo_ptr_incrᵢ=floor(base_accumᵢ₊₁)=3
fifo_base_ptrᵢ=mod(fifo_base_ptrᵢ₋₁+fifo_ptr_incrᵢ₋₁, FIFO_DEPTH)=6+4=10, fifo_ptr_add₂=floor(accum₂[X])=0,0,1,2; fifo_rd_ptr₂[X]=mod(fifo_base_ptr₂+fifo_ptr_add₂[X], FIFO DEPTH)=10,10,11,12. Four output samples are generated by using the data from FIFO locations 10,10,11,12 with corresponding delta(μ)=0, 0.8333 . . . , 0.666 . . . , 0.5.

In output clock cycle 5, i=5, output samples 17 to 20: the delta and FIFO read locations may be calculated as above. Here, four output samples are generated by using the data from FIFO locations 13,14,15,15 with corresponding delta(μ)=0.333 . . . , 0.1666 . . . , 0, 0.8333 . . . .

In output clock cycle 6, i=6, output samples 21 to 24: the delta and FIFO read locations may be calculated as above. Here, four output samples are generated by using the data from FIFO locations 0,1,2,3 with corresponding delta(μ)=0.666 . . . , 0.5, 0.333 . . . , 0.1666 . . . .

In an example digital design with bit precision, the above equations (11)-(17) may be modified as follows, for example, to facilitate integer or fixed-point computations:

Nb=log₂(N);Bits to represent 0 to N−1, (21)

T=Nb+Pbits, (22)

int_accumᵢ=mod (int_accumᵢ₋₁[Pbits−1:0]+N×R_int,2\hat{ }(T+1));T+1 bits, (23)

mod_incrᵢ=(mod_valueᵢ₋₁+R_frac_A)R_frac_B For R_frac_A>0, or “0” for R_frac_A=0, and (24)

mod_accumᵢ=mod (mod_accumᵢ₋₁+N×mod_incrᵢ,2\hat{ }Pbits). (25)

The base accumulation values can be computed as shown in equation (26) or (27):

base_accumᵢ=mod (int_accumᵢ+mod_accumᵢ,2\hat{ }(T+1)), (26)

base_accumᵢ=mod (base_accumᵢ₋₁[Pbits−1:0]+N×(R_int+mod_incrᵢ₋₁),2\hat{ }(T+1)) (27)

The base_accumᵢ may be used to generate N delta values and N FIFO pointers.

The intermediate accumulation values can be computed as shown below:

accumᵢ[0]=base_accumᵢ[Pbits−1:0]; //accumᵢ is N×T, (28)

accumᵢ[1]=base_accumᵢ[Pbits−1:0]+R_int, (29)

accumᵢ[2]=base_accumᵢ[Pbits−1:0]+2×R_int, and (30)

accum_{i[N-}1]=base_accumᵢ[Pbits−1:0]+(N−1)×R_int. (31)

Accordingly, accumᵢ may generally be computed as shown below:

accum_{i[X}]=base_accumᵢ[Pbits−1:0]+(X)×R_int, for X=0,1 . . . N−1. (32)

The delta values can be computed as shown below:

delta_{i[X}]=accum_{i[X}][Pbits−1: Pbits−D]. (33)

The FIFO pointer increment can be computed as shown below:

fifo_ptr_incrᵢ₋₁=base_accum_{i[T}: Pbits], (34)

where fifo_ptr_incrᵢ₋₁ may have a length of Nb+1 bits and may be used to increment the fifo_base_ptr for the next clock cycle.

The FIFO pointer add can be computed as shown below:

fifo_ptr_add_{i[X}]=accum_{i[X][T-}1: Pbits], (35)

where X=0,1 . . . N−1.

The equations (21)-(35) shown above for implementation in a digital hardware design may be operated off of the ungated Fs/N clock.

FIG. 13 provides an example digital hardware implementation for an accumulator 1300 with a parallel structure for generating delta values and buffer pointers for a farrow structure-based FSRC (e.g., the FSRC 1000 of FIG. 10), according to some embodiments of the present disclosure. In some aspects, the accumulator 1300 may be implemented as part of the resample control circuitry 1020 at the FSRC 1000 shown in FIG. 10. For simplicity of illustration, dithering generation is excluded from the illustration in FIG. 13. The accumulator 1300 may implement equations (21)-(35) discussed above.

As shown in FIG. 13, the accumulator 1300 may include a base accumulator 1310 and N adders 1320. The base accumulator 1310 may increment a base accumulation value by N×1/R (e.g., using modulus accumulation as discussed above with reference to equations (21)-(27)). The output (shown by node A) of the base accumulator 1310 may be coupled to N parallel paths 1302. Each of the N adders 1320 may be coupled on one of the N parallel paths 1302. Each of the N adders 1320 may compute an intermediate accumulation value for a respective N using equations (28)-(31) or the generic equation (32). As further shown in FIG. 13, each of the N adders 1320 may generate one of N delta values (e.g., equation (33)) and an offset (e.g., equation (35)) for a corresponding FIFO read pointer of the N FIFO read pointers by adding k×R_int to the incremented base accumulation value, where k varies from 0 to N−1 and R_int corresponds to 1/R represented as a P-bit fixed-point or integer value. For example, R_int may be computed as floor (1/R×2\hat{ }Pbits) as discussed above. As further shown in FIG. 13, the output of each of the N adders 1320 may provide a delta value a corresponding offset (e.g., fifo_ptr_add) for a respective sample X, where an upper bit portion of the adder may provide the offset and a lower bit portion of the adder may provide the delta value.

As an example, P may be 48, T may be 4 (e.g., for N=4 and a FIFO having a size of 4N), and the delta values may be represented by 16 bits. In this example, the base accumulation value (e.g., base_accum) output by the base accumulator 1310 may have a bit-width of 52 bits. The MSB 4 bits of the base accumulation value may be output as the fifo_ptr_incr. At the output of each of the adder 1320, a fifo_ptr_add value may be provided by bits[50:48] of the adder 1320 and a corresponding delta value may be provided by bits[47:32] of the adder 1320.

The FIFO read pointer may be calculated as shown below:

fifo_base_ptrᵢ=fifo_base_ptrᵢ₋₁+fifo_ptr_incrᵢ₋₁, (36)

fifo_rd_ptr_{i[X}]=mod(fifo_base_ptrᵢ+fifo_ptr_add_{i[X}],FIFO DEPTH). (37)

Using equations (36)-(37) with X varying from 0 to N−1, N FIFO read pointers may be generated for reading from the FIFO (e.g., the FIFOs 1012-1018).

As can be seen in the FIG. 13, the accumulator 1300 may perform delta value and FIFO pointer calculation based on a single input R_int that is dependent on the rate change factor R. Accordingly, the implementation of the accumulator 1300 may be suitable for arbitrary sample rate conversion. In other words, an FSRC 1000 using the accumulator 1300 can advantageously allow for a dynamic configuration of a rate change R (e.g., via software or firmware register write). Further, having the accumulator 1300 to compute all the FIFO pointer parameters can provide for a simple efficient configuration scheme (e.g., without having large number of registers or memory for programming FIFO pointer parameters).

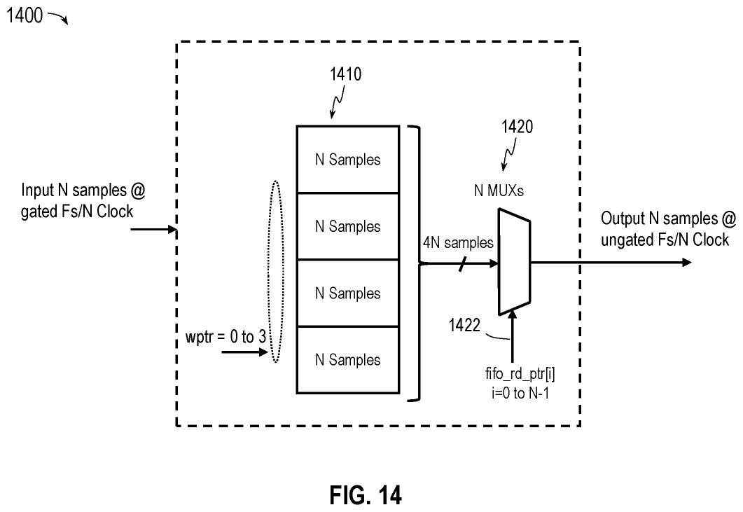

FIG. 14 provides an example digital hardware implementation scheme 1400 for FIFO data transfers, according to some embodiments of the present disclosure. In some aspects, the scheme 1400 may be implemented as part of the resampler control circuitry 1020 in the FSRC 1000 of FIG. 10. As shown in FIG. 14, the scheme 1400 may include a FIFO 1410. (e.g., memory such as random-access memory (RAM)). In the illustrated example, the FIFO 1410 may have a FIFO size or depth of 4N. However, the FIFO size can be scaled to any suitable value (e.g., integer multiples of N). The scheme 1400 may further include N number of MUXs 1420. Each of the N MUXs 1420 may have inputs connected to respective outputs of the FIFO 1410. For example, the FIFO 1410 shown in FIG. 14 may have 4N number of locations, and thus each MUX 1420 may have 4N lines each coupled to one of the FIFO 1410 locations. A selection line 1422 for each of the N MUXs 1420 may be controlled by a corresponding fifo_rd_ptr[i] (for i=0 to N−1) computed in accordance with equation (37). Each of the MUX 1420 may select one of the 4N samples from the FIFO 1410 according to the selection line 1422.

As further shown, the scheme 1400 may operate on N input samples input at a rate of the gated Fs/N clock. The N input samples may correspond to samples output by the filters 502-508. The MUXs 1420 may provide N output samples (as selected by the MUX 1420) at a rate of the ungated Fs/N clock. Some consecutive samples of the N input samples may correspond to the same sample (filtered sample) depending on R and the particular time instances while the N output samples may be N unique samples.

Accordingly, in some aspects, the resampler control circuitry 1020 may operate based on a clock signal divided from Fₒᵤₜ based on N, and generate N delta values and N FIFO read pointers in parallel (e.g., as shown in FIG. 13) within one clock cycle of the clock signal.

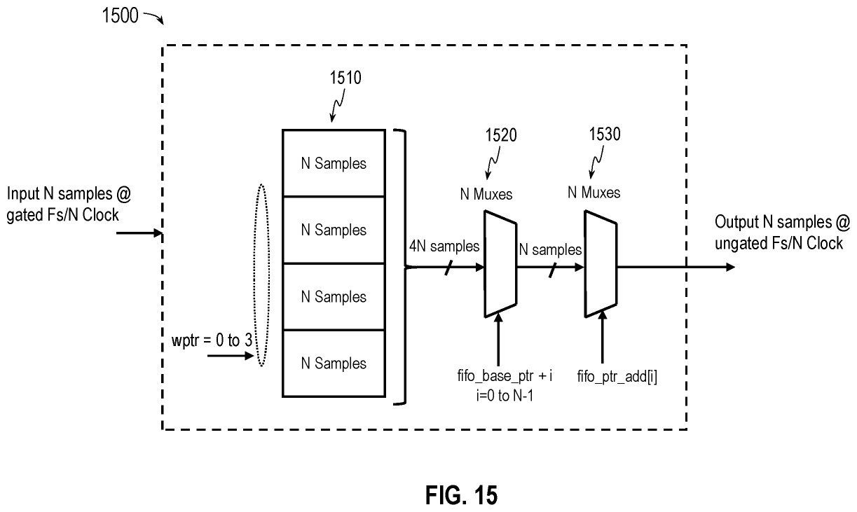

FIG. 15 provides another example digital hardware implementation scheme 1500 for FIFO data transfers, according to some embodiments of the present disclosure. In some aspects, the scheme 1500 may be implemented as part of the resampler control circuitry 1020 in the FSRC 1000 of FIG. 15. As shown in FIG. 15, the scheme 1500 may include a FIFO 1510 similar to the FIFO 1410. Further, the scheme 1500 may operate on N input samples input at a rate of the gated Fs/N clock and provide N output samples at a rate of the ungated Fs/N clock similar to the scheme 1400. However, the scheme 1500 may have 2 levels of MUXs with a first level of N MUXs 1520 and a second level of N MUXs 1530. The MUXs 1520 may read N consecutive locations from the FIFO 1510 starting from fifo_base_ptrᵢ (computed in accordance with equation (37)). The MUXs 1530 may map the data read from the FIFO to output data.

In both the scheme 1400 of FIG. 14 and the scheme 1500, for each cycle (of Fsl/N clock), N samples may be written to the consecutive FIFO addresses (FIFO locations). In the examples of FIGS. 14 and 15, wrptr may have values from 0 to 3 for the FIFO depth of 4×N. For each cycle of Fsl/N clock, N consecutive samples may be written to FIFO with a start address represented by wrptr×N. FIFO write and read operations may start after both Fsh/N, Fsl/N clocks are generated and the reset values of wrptr and fifo_base_ptr may be chosen to ease timing implementation. Comparing the FIG. 14 and FIG. 15, the scheme 1400 may provide for a more area efficient implementation of FIFO transfers, e.g., including a total of N MUXs rather a total of 2N MUXs as in the scheme 1500.

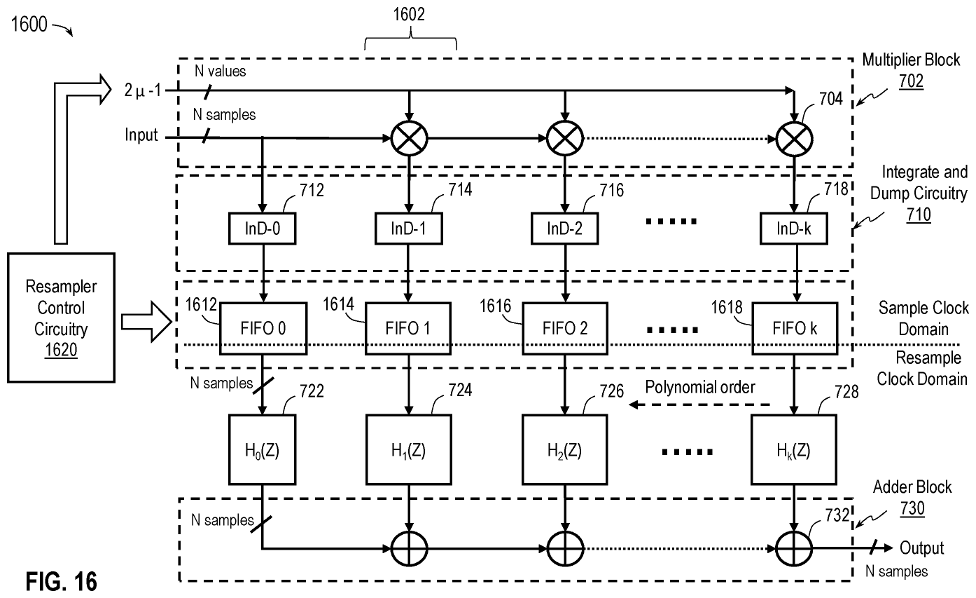

FIG. 16 provides an example farrow structure-based FSRC 1600 with a parallel structure for decimation, according to some embodiments of the present disclosure. The FSRC 1600 of FIG. 16 shares many elements with the FSRC 700 of FIG. 7; for brevity, a discussion of these elements is not repeated, and these elements may take the form of any of the embodiments disclosed herein. However, the FSRC 1600 may utilize a parallel architecture to facilitate interpolation at high sampling rates (e.g., in the GHz range).

As shown in FIG. 16, the FSRC 1600 may include a multiplier block 702, integration and dump circuitry 710, a plurality of FIFOs (shown as 1612-1618 and depicted as FIFO 0 to FIFO k), and an adder block 730. Each FIFO 1612-1618 may be coupled between the output of a respective one of the integration and dump sub-circuitries 712-718 and the input of a respective one of the plurality of filters 722-728. For example, the FIFO 1612 (FIFO 0) is coupled between the output of the integration and dump sub-circuitries 712 and the input of the filter 502, the FIFO 1614 (FIFO 1) is coupled between the output of the integration and dump sub-circuitries 714 and the input of the filter 724, and so on. The FSRC 1600 may operate at a clock rate of Fs/N but may operate on N samples in each clock cycle. That is, the FSRC 1600 may receive input samples at a rate of Fin and output rate-converted samples at a rate Fₒᵤₜ=Fᵢₙ/R, where R is a rate change factor greater than 1, but the digital hardware logics or circuitries may operate at Fs/N. Accordingly, in some aspects, the FSRC 1000 may include N instances of the multiplier block 702, N instances of the integration and dump circuitry 710, N instances of the filters 722-728 to produce N samples at the output of each of the filters 722-728 in one clock cycle. The FSRC 1000 may further include N instances of the adder block 730 to produce N output samples in one clock cycle.

As can be seen, the FSRC of FIG. 16 differs from the FSRC 700 of FIG. 7 not only in operating with N samples but in using FIFOs (e.g., the FIFOs 1612-1618) to transfer data from an input sample clock domain (Fsh/N clock) to an output resample domain (Fsl/N clock). For each clock cycle, N samples may be processed. Accordingly, in some aspects, the resampler control circuitry 1620 may operate based on a clock signal divided from Fᵢₙ base on N and may generate N delta values and N FIFO write pointers in parallel within one clock cycle of the clock signal. In some aspects, each multiply symbol shown in FIG. 16 may perform N multiplications of data with corresponding 2×μ−1.

As further shown in FIG. 16, the FSRC 1600 may include resampler control circuitry 1620 for calculating the delta values and FIFO read/write pointers. The equations used in delta generation for decimation may be similar to the equations (e.g., equations (11)-(37)) and/or using the accumulator 1300 of FIG. 13 for interpolation described above. However, for each cycle (of gated Fs/N), each FIFO 1612-1618 may have N consecutive reads and writing to the FIFOs 1612-1618 by the respective integration and dump sub-circuitries 712-718 may be calculated similar to the FIFO read pointers for the FSRC 1000 of FIG. 10. In other words, output samples of the integration and dump circuitry 710 for each of the plurality of filters 722-728 may be stored at a respective one of the plurality of FIFOs 1012-1018 based on FIFO write pointers (e.g., represented by fifo_wr_ptr[X] for X varying from 0 to N−1) and the stored samples may be read from each of the FIFOs 1012-1018 for processing by a respective filter of the plurality of filters 722-728. The calculation of the N FIFO write pointers will be discussed more fully below.

To facilitate generation of N delta values and N FIFO read/write pointers in each cycle for decimation, a set of parameters including a base accumulation value, an intermediate accumulation, a delta value, a FIFO pointer increment, a FIFO pointer offset, a FIFO write base pointer, a FIFO read pointer, and a FIFO write pointer represented by base_accumᵢ, accumᵢ[X], deltaᵢ[X], fifo_ptr_incrᵢ₋₁, fifo_ptr_addᵢ[X], fifo_wrt_base_ptrᵢ, fifo_rd_ptr ᵢ[X], and fifo_wr_ptrᵢ[X], respectively. The values for base_accumᵢ, accumᵢ[X], deltaᵢ[X], fifo_ptr_incrᵢ₋₁, fifo_ptr_addᵢ[X] may be computed by the resample control circuitry 1620 using equations (21)-(35).

The FIFO write base pointer may be computed as shown below:

fifo_wr_base_ptrᵢ=mod(fifo_wr_base_ptrᵢ₋₁+fifo_ptr_incrᵢ₋₁,FIFO DEPTH). (38)

The FIFO pointer add (e.g., offset) can be computed as shown below:

fifo_ptr_add_{i[X}]=accum_{i[X][T-}1: Pbits], for X=0,1 . . . N−2. (39)

An integration and dump flag value, InDᵢ[X], may be computed as shown below:

$$ln {D}_{i} [ X ] = fifo \_ ptr {\_ add}_{i} [ X + 1 ] > fifo \_ ptr {\_ add}_{i} [ X ] , for X = 0 , 1 … N ‐ 2. = fifo \_ ptr {\_ incr}_{i} > fifo \_ ptr {\_ add}_{i} [ X ] , for X = N ‐ 1. \qquad ( 40 )$$

In an aspect, InDᵢ[X] may correspond to an inverted overflow value.

An individual integration and dump sub-circuitry (e.g., one of the integration and dump sub-circuitries 712-718) may compute the following:

InD_data_{i[X]=InD}_data_{i[X-}1]×InD_{i[X-}1]+input_data_ind_{i[X}] for X=1,2 . . . N−1, (41)

InD_dataᵢ[0]=InD_data_{i-11[N-}1]×InD_{i-1[N-}1]+input_data_indᵢ[0]. (42)

where input_data_indᵢ may be data input to the respective individual integration and dump sub-circuitry. Accordingly, in some aspects, the integration and dump circuitry 710 (or more specifically an individual integration and dump sub-circuitry 712, 714, 716, or 718) may sum the outputs of the multiplier block by multiplying a first output (e.g., InD_dataᵢ[X−1]) of the outputs of the multiplier block by a value (e.g., InDᵢ[X−1]) that is based on a comparison between two successive FIFO write pointers of the N FIFO write pointers to produce a product value and summing a second output (e.g., input_data_indᵢ[X]) of the outputs of the multiplier block 702.

The following shows an example pseudo-code for writing integration data (output by one of the integration and dump sub-circuitries 712-718) to a respective FIFO (e.g., one of the FIFOs 1012-1018) based on (decoded from) fifo_ptr_add[N−1:0]:

```
For (X=0; X=N-1; X++)
  For (Y=X; Y=N-1; Y++) // this may be implemented with “if else” in a
hardware implementation
    If ((fifo_ptr_addᵢ[Y]==X) && InDᵢ[Y])
      input_ptrᵢ[X] = Y;
      findᵢ[X] = 1;
      Break; // When if condition is satisfied then the second for loop
      will exit
    Endif
  Endfor
  If (findᵢ[X]==0)
    input_ptrᵢ[X] = N-1; // to fill the remaining entries in input_ptrᵢ
Endfor
```

In the above pseudo-code, X may represent the sample number within a block of N samples (or clock cycle i), input_ptrᵢ[X] may represent the location or index of the integration data buffer (e.g., InD_data) in which the stored integration data is to be written to the FIFO for the X-th sample in the block of N samples (or clock cycle i), and findᵢ[X] may be indicative of whether a value is generated for the X-th sample. For instance, when there is an insufficient number of samples (e.g., N samples) to be written to the FIFO in the clock cycle i (meaning that not all input_ptr values can be generated), findᵢ[X] is used to facilitate the filling of the remaining input_ptrs (that cannot not generated) as will be shown in an example below.

The data to be written to the FIFO may be as shown below:

data_to_fifo_{i[X]=InD}_dataᵢ[input_ptr_{i[X}]]. (43)

The fifo_ptr_incrᵢ value may represent the number of samples that may be written to the FIFO for each Fs/N ungated clock, starting from an address indicated by fifo_wr_base_ptrᵢ and the data to be written to the FIFO may correspond to the bottom fifo_ptr_incrᵢ samples from data_to_fifoᵢ.

In an example, N=9. Assuming fifo_wr_base_ptrᵢ=10, fifo_ptr_addᵢ[0:7]={0,0,1,2,3,3,4,5}, fifo_ptr_incrᵢ=6, and InDᵢ₋₁[7]=1. Then, InDᵢ₋₁[7]=1 may indicate that the integrated data, InD_dataᵢ₋₁₁[N−1], is written to the FIFO in a previous cycle (e.g., the (i−1)-th cycle). The fifo_ptr_incrᵢ=6 may indicate that in the present cycle, 6 samples may be written to the FIFO.

Further, as per equation (40), InDᵢ[0:7]={0,1,1,1,0,1,1,1}.

As per equations (41) and (42), InD_dataᵢ[0:7]={input_data_indᵢ[0], input_data_indᵢ[0]+input_data_indᵢ[1], input_data_indᵢ[2], input_data_indᵢ[3], input_data_indᵢ[4], input_data_indᵢ[4]+input_data_indᵢ[5], input_data_indᵢ[6], input_data_indᵢ[7]}.

Based on the for loop in the pseudo-code above, findᵢ[0:7]={1,1,1,1,1,1,0,0} and input_ptrᵢ[0:7]={1,2,3,5,6,7,7,7}. Here, findᵢ[0:7] indicates that there is a value generated for each of the first six locations but not the last two locations. Accordingly, the last two locations of the input_ptr (e.g., input_ptrᵢ[6:7]) are filled with the value 7.

As per equation (43), data_to_fifoᵢ[0:7]={InD_dataᵢ[1], InD_dataᵢ[2], InD_dataᵢ[3], InD_dataᵢ[5], InD_dataᵢ[6], InD_dataᵢ[7], InD_dataᵢ[7], InD_dataᵢ[7]}.

As fifo_ptr_incrᵢ=6, only the data_to_fifoᵢ[0:5] may be written to the FIFO starting from fifo_wr_base_ptrᵢ+0 to fifo_wr_base_ptrᵢ+(6-1) locations.

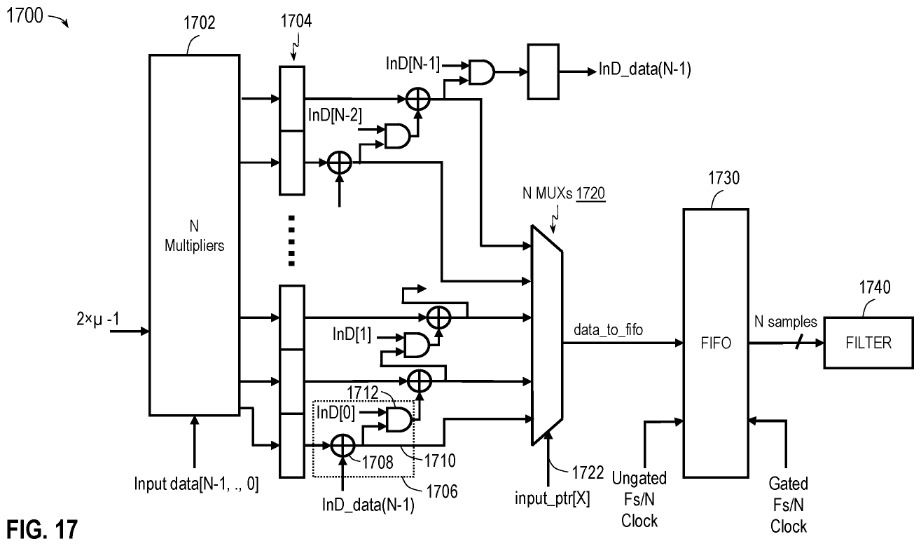

FIG. 17 provides an example digital hardware implementation scheme 1700 for integration and dump, according to some embodiments of the present disclosure. In some aspects, the scheme 1700 can be implemented by the integration and dump circuitry 710 in the FSRC 1600 of FIG. 16. For simplicity of illustration and discussion, the scheme 1700 is shown for operations associated with a particular polynomial order (e.g., a branch 1602 shown in FIG. 16 for the first order). However, similar operations may be applied to any one of the 0-th order to k-th order branch).

As shown in FIG. 17, the scheme 1700 may include N multipliers 1702 (e.g., corresponding to N instances of a multiplier 704) in the multiplier block 702 of the FSRC 1600). The N multipliers may each multiple one of the input samples (depicted as Input data[N−1, . . . , 0]) by a respective delta value (e.g., 2×μ−1) to provide a multiplied data 1704. Each multiplied data 1704 may be provided to an integration and dump sub-circuitry. In order not to clutter drawings provided in FIG. 17, reference numerals are shown for only one integration and dump sub-circuitry 1706 (e.g., corresponding to an individual integration and dump sub-circuitry 712, 714, 716, or 718 in the FSRC 1600 of FIG. 16). As shown, the integration and dump sub-circuitry 1706 may include an accumulator 1708 and an AND gate 1712. The accumulator 1708 may add a multiplied data 1704 to a previous stored integrated data (e.g., InD_data[k−1] for a current sample index k or InD_data[N−1] for the first sample of a block of N samples) to generate a current integrated value 1710. The AND gate 1712 may apply an AND operation to current integrated value 1710 and a respective InD (e.g., computed in accordance with equation (40)). The AND gate 1712 may output the current integrated value 1710 to an integration and dump sub-circuitry associated with a next sample if the respective InD is 1. If, however, the respective InD is 0, the AND gate 1712 may output a 0 to the integration and dump sub-circuitry associated with a next sample. As discussed above, InD may operate as an inverted overflow value. As such, the arrangement of the accumulator 1708 and the AND gate 1712 may implement the integration and dump operations as discussed above where an overflow equals to 1 may cause the current integrated value to be output and the integrator to be reset. Alternatively, when an overflow equals to 0, the integrator may continue to integrate with the next input (a next multiplied data 1704). As can be seen, the arrangement of the accumulator 1708 and the AND gate 1712 are repeated and each coupled to one of the multiplied data 1704.

As further shown, the scheme 1700 may further include N MUXs 1720. The current integrated value 1710 output by the accumulator 1708 may be an input to each of the N MUXs 1720. Each of the N MUXs 1720 may select one of the N inputs each from one of the accumulator and AND gate arrangement (e.g., integration and dump sub-circuitry 1706). The selection line to each of the N MUXs 1720 may be one of N input_ptr[X], where X varies from 0 to N−1, for example, computed as discussed above with reference to the pseudo-code.

As further shown, the scheme 1700 may include a FIFO 1730 (e.g., corresponding to a FIFO 1612, 1614, 1616, or 1618 in the FSRC 1600 of FIG. 16) coupled to the outputs of the MUXs 1720. The MUXs 1720 may write data (e.g., data_to_fifo shown in equation (43)) to the FIFO 1730 according to the input_ptr[X]. For instance, the MUXs 1720 may write a fifo_ptr_incr (e.g., computed as shown in equation (34)) number of samples to the FIFO 1730 based on a fifo_wrt_base_ptr (e.g., computed as shown in equation (38)).

As further shown, the scheme 1700 may include a filter 1740 (e.g., corresponding to a filter 722, 724, 726, or 728 in the FSRC 1600 of FIG. 16) coupled to the output of the FIFO 1730. Samples may be written to the FIFO 1730 based on an ungated Fs/N clock and read from the FIFO 1730, for example, for input to the filter 1740, based on a gated Fs/N clock.

In some aspects, the resampler control circuitry 1620 may implement part of the scheme 1700, for example, including the N MUXs 1720 coupled to N integration and dump sub-circuitries (e.g., the integration and dump sub-circuitry 1706) and generating a selection signal 1722 for each MUX 1720.

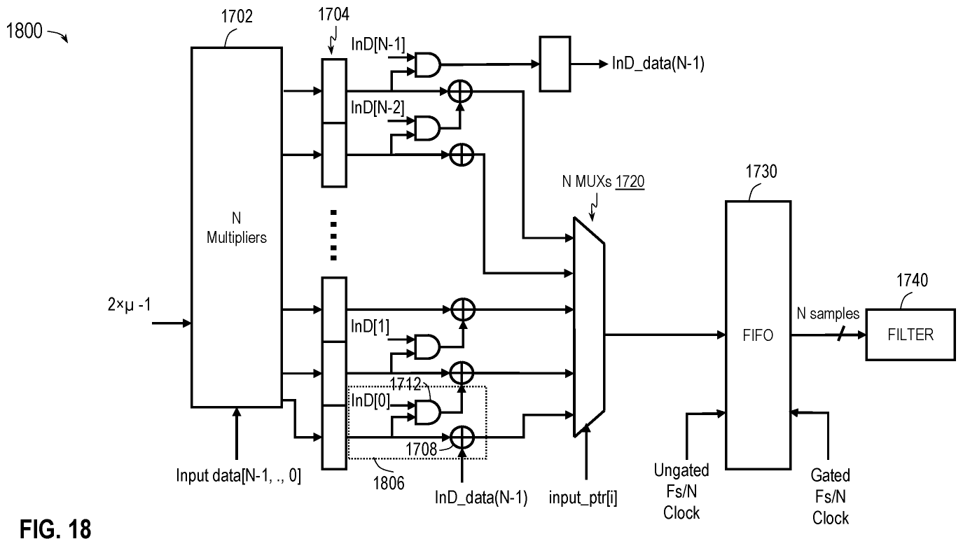

FIG. 18 provides an example digital hardware implementation scheme 1800 for integration and dump, according to some embodiments of the present disclosure. In some aspects, the scheme 1800 can be implemented by the integration and dump circuitry 710 in the FSRC 1600 of FIG. 16. For simplicity of illustration and discussion, the scheme 1800 is shown for operations associated with a particular polynomial order (e.g., a branch 1602 shown in FIG. 16 for the first order). However, similar operations may be applied to any one of the 0-th order to k-th order branch). As can be seen, the scheme 1800 shares many elements with the scheme 1700 of FIG. 17; for brevity, a discussion of these elements is not repeated, and these elements may take the form of any of the embodiments disclosed herein. The scheme 1800 may simplify the integration and dump operation of FIG. 17 for 1≤R≤2. In the scheme 1800, the adjacent multiplied data 1704 from the multiplier 1702 may be added where the AND gate 1712 may apply an AND operation to the multiplied data 1704 and a respective InD and input to a next accumulator 1708 (shown by the arrangement of the integration and dump sub-circuitry 1806).

In some aspects, for a given rate change, by programming different a reset value for the accumulator (e.g., the base accumulation value, base_accum₀, discussed above) used for calculating the delta values, a different fractional delay may be achieved. The following may apply for rate change:

For interpolation: Max delay (range)=FSRC input sample delay
For decimation: Max delay (range)=FSRC output sample delay
Step size (precision)=Range/(2\hat{ }Pbits), if Pbits are very high this may be simplified to: observable Step size (precision)=Range/(2\hat{ }delta_bit_width)

In a 1× mode (meaning that there is no sample rate change, by using the same hardware, a fractional delay may be achieved by fixing the delta (μ) value to the required fractional delay, step size (precision)=sample_delay/(2\hat{ }delta_bit_width). Delta generation may be ignored in 1× mode, but all other modules may be reused.

Accordingly, in some aspects, the resample control circuitry 1020 in the FSRC 1000 of FIG. 10 for interpolation and/or the resampler control circuitry 1620 in the FSRC 1600 of FIG. 16 may initialize the base accumulation value (e.g., the base_accum) to a value (e.g., an integer value for fixed-point implementation) corresponding to a fractional sample delay.

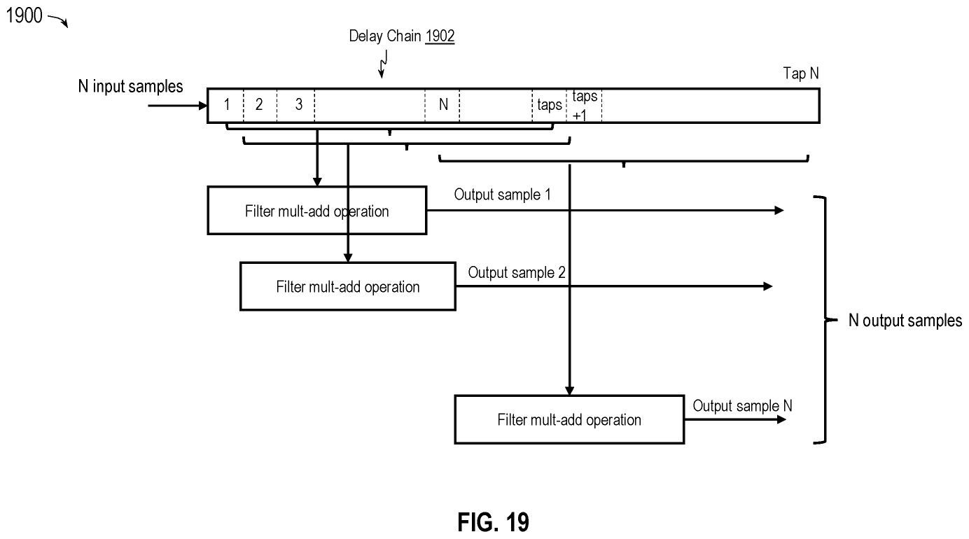

FIG. 19 shows an example FIR filter parallel implementation scheme 1900 using N input samples to generate N filter output samples. In an aspect, the FSRC 1000 of FIG. 10 and/or the FSRC 1600 of FIG. 16 may utilize the scheme 1900 to implement the filters 502-508 and/or 722-728, respectively. As shown in FIG. 19, samples are input into the delay chain 1902 in blocks of N samples, and each output sample is generated by performing multiply-add operations according to the coefficients or taps of the FIR.

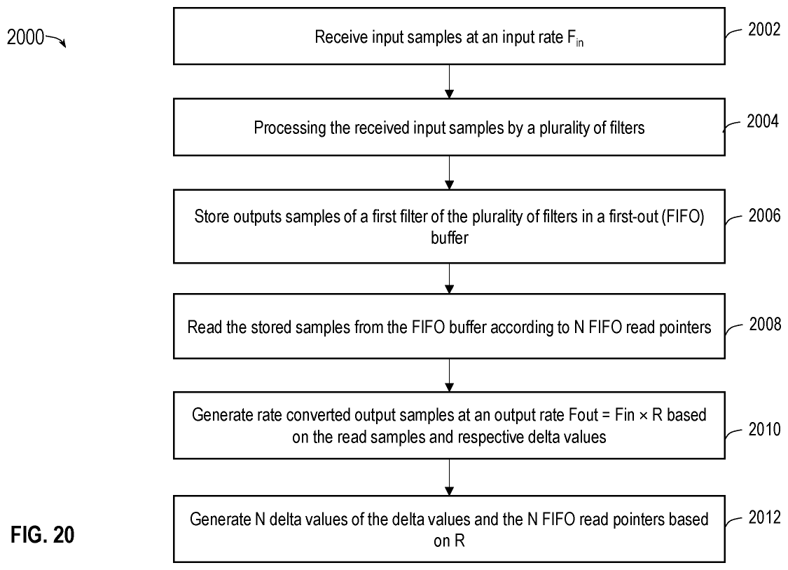

FIG. 20 is a flow diagram of a method 2000 for performing sample rate conversion at high sampling rates for interpolation, according to some embodiments of the present disclosure. The method 2000 can be implemented by the FSRC 1000 of FIG. 10 using similar mechanisms as discussed above with reference to FIGS. 10-15 and 19. Although the operations of the method 2000 may be illustrated with reference to particular embodiments of the FSRC 1000 disclosed herein, the method 2000 may be performed using any suitable hardware components and/or software components. Operations are illustrated once each and in a particular order in FIG. 20, but the operations may be performed in parallel, reordered, and/or repeated as desired.

The method 2000 may perform a sample rate conversion R with an input rate Fᵢₙ and output rate Fₒᵤₜ=Fᵢₙ×R, where R is a fraction greater than 1. For example, at 2002, input samples may be received at the input rate Fᵢₙ.

At 2004, the received input samples may be processed by a plurality of filters. The filters may be polynomial-based filters, for example, corresponding to the filters 502-508.

At 2006, the outputs samples of a first filter of the plurality of filters may be stored in a FIFO buffer, for example, correspond to the FIFO 1012, 1014, 1016, or 1018.

At 2008, the stored samples may be read from the FIFO buffer according to N FIFO read pointers.

At 2010, rate-converted output samples may be generated at the output rate Fₒᵤₜ based on the read samples and respective delta values, where each of the delta values (e.g., deltaᵢ[X] or μ[X] where X may vary from 0 to N−1) corresponds to a time interval from one of the receive input samples.

At 2012, N delta values of the delta values and the N FIFO read pointers may be generated in parallel (or simultaneously) based on R, where N is an integer greater than 1. In an aspect, the parallel generation of the delta values and the N FIFO read pointers may utilize mechanisms discussed above with reference to FIG. 13.

In some aspects, the N delta values and the N FIFO read pointers is based on a clock signal divided from Fₒᵤₜ based on N, and the N delta values and the N buffer read pointers are generated in parallel within one clock cycle of the clock signal. In some aspects, as part of generating the N delta values and the N FIFO read pointers, a base accumulation value may be incremented by N×1/R and the N delta values and the N buffer read pointers may be generated based on the incremented base accumulation value. In some aspects, as part of generating the N delta values and the N FIFO read pointers, a modulo operation may be applied to the base accumulation value before the incrementing. In some aspects, as part of generating the N delta values and the N FIFO read pointers, the N delta values may be generated by adding k×1/R to the incremented base accumulation value, where k varies from 0 to N−1.

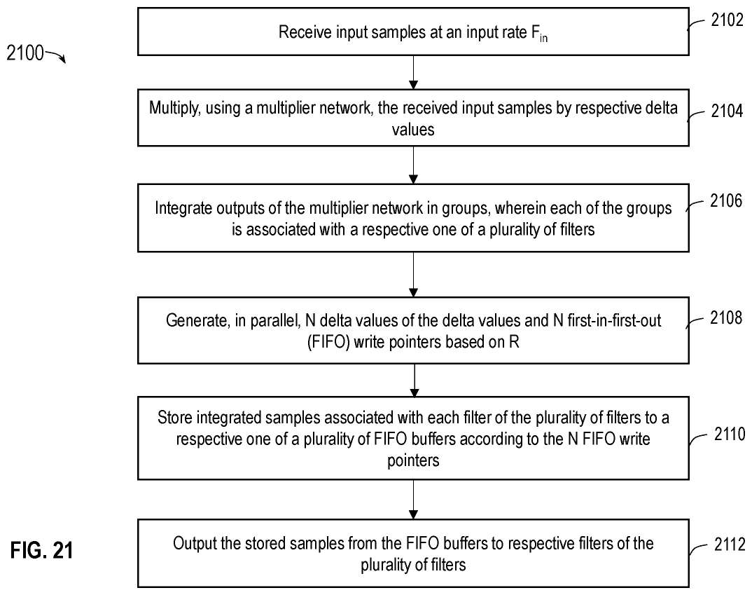

FIG. 21 is a flow diagram of a method 2100 for performing sample rate conversion at high sampling rates for decimation, according to some embodiments of the present disclosure. The method 2100 can be implemented by the FSRC 1600 of FIG. 16 using similar mechanisms as discussed above with reference to FIGS. 13 and 16-19. The method 2100 can be implemented by the FSRC 1600 of FIG. 16. Although the operations of the method 2100 may be illustrated with reference to particular embodiments of the FSRC 1600 disclosed herein, the method 2100 may be performed using any suitable hardware components and/or software components. Operations are illustrated once each and in a particular order in FIG. 21, but the operations may be performed in parallel, reordered, and/or repeated as desired.

The method 2100 may performing a sample rate conversion R with an input rate Fᵢₙ and output rate Fₒᵤₜ=Fᵢₙ/R, where R is a fraction greater than 1. For example, at 2102, input samples may be received at the input rate Fᵢₙ.

At 2104, the received input samples may be multiplied, using a multiplier block (e.g., the multiplier block 702), by respective delta values (e.g., deltaᵢ[X] or μ[X]). Each of the delta values corresponds to a time interval from a sample time of one of output samples at the output rate Fₒᵤₜ.

At 2106, outputs of the multiplier block may be integrated in groups, where each of the groups is associated with a respective one of a plurality of filters (e.g., the filters 722-728).

At 2108, N delta values of the delta values and N FIFO write pointers may be generated in parallel based on R, where N is an integer greater than 1. In an aspect, the parallel generation of the delta values and the N FIFO read pointers may utilize mechanisms discussed above with reference to FIG. 13.

At 2110, integrated samples associated with each filter of the plurality of filters may be stored at a respective one of a plurality of FIFO buffers according to the N FIFO write pointers.

At 2112, the stored samples from the FIFO buffers may be output o to respective filters of the plurality of filters.

In some aspects, the N delta values and the N FIFO write pointers may be generated based on a clock signal divided from Fᵢₙ based on N, where the N delta values and the N FIFO write pointers may be generated in parallel within one clock cycle of the clock signal. In some aspects, a number of the outputs for the integrating is based on an overflow factor dependent on R. In some aspects, as part of the integrating, a first output of the outputs of the multiplier block may be multiplied by a value based on a comparison between two successive FIFO write pointers of the N FIFO write pointers to produce a product value and the product value may be summed with a second output of the outputs of the multiplier block. In some aspects, as part of generating the N delta values and the N FIFO write pointers, a base accumulation value may be incremented by N×1/R and the N delta values and the N FIFO write pointers may be generated based on the incremented base accumulation value. In some aspects, as part of generating the N delta values and the N FIFO write pointers, a modulo operation may be applied to the base accumulation value before the incrementing. In some aspects, as part of generating the N delta values and the N FIFO write pointers, the N delta values may be generated by adding k×1/R to the incremented base accumulation value, where k varies from 0 to N−1.

### Examples

Example 1 includes a sample rate converter (SRC) for implementing a rate conversion R, where the SRC receives input samples at an input rate Fᵢₙ and outputs samples at an output rate Fₒᵤₜ=Fᵢₙ×R, and where R is a fractional value greater than 1, the SRC including a plurality of filters to process the received input samples; a multiplier and adder block to generate the output samples for the SRC based on respective delta values and outputs of the plurality of filters, where each of the delta values is associated with a time interval (e.g., a fraction of an input sampling time interval) from one of the received input samples; and a plurality of buffers to buffer samples between the plurality of filters and the multiplier and adder block based at least in part on N buffer read pointers, where N is an integer greater than 1; and resampler control circuitry to generate N delta values of the delta values and the N buffer read pointers in parallel based on R.

In Example 2, the SRC of Example 1 can optionally include where each one of the plurality of filters is associated with a different polynomial order.

In Example 3, the SRC of any one of Examples 1-2 can optionally include where the multiplier and adder block includes multipliers and adders arranged based on a polynomial-based filter structure.

In Example 4, the SRC any one of Examples 1-3 can optionally include where each buffer of the plurality of buffers stores output samples of a respective one of the plurality of filters, and where the stored samples are read from each buffer based on the N buffer read pointers.

In Example 5, the SRC of any one of Examples 1˜4 can optionally include where the resampler control circuitry further includes N multiplexers (MUXs), each of the N MUXs having inputs connected to respective outputs of a first buffer of the plurality of buffers and outputs connected to the multiplier-adder block; and the resampler control circuitry further generates a selection signal to each of the N MUXs based on a respective one of the N buffer read pointers.

In Example 6, the SRC of any one of Examples 1-5 can optionally include where the resampler control circuitry operates based on a clock signal divided from Fₒᵤₜ based on N, and where the N delta values and the N buffer read pointers are generated in parallel within one clock cycle of the clock signal.

In Example 7, the SRC any one of Examples 1-6 can optionally include where the resampler control circuitry increments a base accumulation value by N×1/R and generates the N delta values and the N buffer read pointers based on the incremented base accumulation value.

In Example 8, the SRC any one of Examples 1-7 can optionally include where the resampler control circuitry applies a modulo operation to the base accumulation value before the incrementing.

In Example 9, the SRC of any one of Examples 1-8 can optionally include where the resampler control circuitry generates the N delta values by adding k×1/R to the incremented base accumulation value, where k varies from 0 to N−1.

In Example 10, the SRC of any one of Examples 1-9 can optionally include where the resampler control circuitry includes a base accumulator to increment a base accumulation value by N×1/R; and N adders each generating one of the N delta values and an offset for a corresponding buffer read pointer of the N buffer read pointers by adding k×R_int to the incremented base accumulation value, where k varies from 0 to N−1 and R_int corresponds to 1/R represented as a P-bit integer value.

In Example 11, the SRC of any one of Examples 1-10 can optionally include where an output of a first adder of the N adders includes a first bit portion corresponding to a respective one of the N delta values; and a second bit portion corresponding to an offset for a respective one of the N buffer read pointers.

In Example 12, the SRC of any one of Examples 1-11 can optionally include where the base accumulation value is initialized according to a predetermined fractional delay.

Example 13 includes a sample rate converter (SRC) for implementing a rate conversion R, where the SRC receives input samples at an input rate Fᵢₙ and outputs samples at an output rate Fₒᵤₜ=Fᵢₙ/R, and where R is a fractional value greater than 1, the SRC including a multiplier block to multiply each of the received input samples by a respective one of delta values, where each of the delta values is associated with a time interval (e.g., a fraction of an output sampling time interval) from a sample time of one of the SRC output samples; integration and dump circuitry to sum outputs of the multiplier block; and resampler control circuitry to generate N delta values of the delta values and N buffer write pointers in parallel, where N is an integer greater than 1; a plurality of filters; and a plurality of buffers to buffer samples between the integration and dump circuitry and the plurality of filters based at least in part on the N buffer write pointers.

In Example 14, the SRC of Example 13 can optionally include where each one of the plurality of filters is associated with a different polynomial order.

In Example 15, the SRC of any one of Examples 13-14 can optionally include where a number of the outputs for the summing at the integration and dump circuitry is based on an overflow factor dependent on R.

In Example 16, the SRC of any one of Examples 13-15 can optionally include where the integration and dump circuitry includes a plurality of integration and dump sub-circuitries each coupled to a respective filter of the plurality of filters to generate a sample for input to the respective filter based on a sum of a first output and a second output of the outputs of the multiplier block.

In Example 17, the SRC of any one of Examples 13-16 can optionally include where the integration and dump circuitry sums the outputs of the multiplier block by multiplying a first output of the outputs of the multiplier block by a value based on a comparison between two successive buffer write pointers of the N buffer write pointers to produce a product value and summing a second output of the outputs of the multiplier block.

In Example 18, the SRC of any one of Examples 13-17 can optionally include where output samples of the integration and dump circuitry for each of the plurality of filters are stored at a respective one of the plurality of buffers based on the N buffer write pointers, and where the stored samples are read from each buffer for processing by a respective filter of the plurality of filters.

In Example 19, the SRC of any one of Examples 13-18 can optionally include where the resampler control circuitry further includes N multiplexers (MUXs), each of the N MUXs having inputs connected to the integration and dump circuitry and outputs connected to respective inputs of a first buffer of the plurality of buffers; and the resampler control circuitry further generates a selection signal to each of the N MUXs based on a respective one of the N buffer write pointers.

In Example 20, the SRC of any one of Examples 13-19 can optionally include where the resampler control circuitry operates based on a clock signal divided from Fᵢₙ based on N, and where the N delta values and the N buffer write pointers are generated in parallel within one clock cycle of the clock signal.

In Example 21, the SRC of any one of Examples 13-20 can optionally include where the resampler control circuitry increments a base accumulation value by N×1/R and generates the N delta values and the N buffer write pointers based on the incremented base accumulation value.

In Example 22, the SRC of any one of Examples 13-21 can optionally include where the resampler control circuitry applies a modulo operation to the base accumulation value before the incrementing.

In Example 23, the SRC of any one of Examples 13-22 can optionally include where the resampler control circuitry generates the N delta values by adding k×1/R to the incremented base accumulation value, where k varies from 0 to N−1.

In Example 24, the SRC of any one of Examples 13-23 can optionally include where the resampler control circuitry includes a base accumulator to increment a base accumulation value by N×1/R; and N accumulators each generating one of the N delta values and an offset for a corresponding buffer write pointer of the N buffer write pointers by adding k×R_int to the incremented base accumulation value, where k varies from 0 to N−1 and R_int corresponds to 1/R represented as a P-bit integer value.

In Example 25, the SRC of any one of Examples 13-24 can optionally include where the base accumulation value is initialized according to a predetermined fractional delay.

Example 26 includes a method for performing a sample rate conversion R with an input rate Fᵢₙ and output rate Fₒᵤₜ=Fᵢₙ×R, where R is a fraction greater than 1, the method including receiving input samples at the input rate Fᵢₙ; processing the received input samples by a plurality of filters; storing outputs samples of a first filter of the plurality of filters in a first-out (FIFO) buffer; reading the stored samples from the FIFO buffer according to N FIFO read pointers; generating rate-converted output samples at the output rate Fₒᵤₜ based on the read samples and respective delta values, where each of the delta values corresponds to a time interval from one of the received input samples; and generating, in parallel, N delta values of the delta values and the N FIFO read pointers based on R, where N is an integer greater than 1.

In Example 27, the method of Example 26, where the generating the N delta values and the N FIFO read pointers is based on a clock signal divided from Fₒᵤₜ based on N, and where the N delta values and the N buffer read pointers are generated in parallel within one clock cycle of the clock signal.

In Example 28, the method of any one of Examples 26-27 can optionally include where the generating the N delta values and the N FIFO read pointers includes incrementing a base accumulation value by N×1/R; and generating the N delta values and the N buffer read pointers based on the incremented base accumulation value.

In Example 29, the method of any one of Examples 26-28 can optionally include where the generating the N delta values and the N FIFO read pointers further includes applying a modulo operation to the base accumulation value before the incrementing.

In Example 30, the method of any one of Examples 26-29 can optionally include where the generating the N delta values and the N FIFO read pointers further includes generating the N delta values by adding k×1/R to the incremented base accumulation value, where k varies from 0 to N−1.

Example 31 includes a method for performing a sample rate conversion R with an input rate Fᵢₙ and output rate Fₒᵤₜ=Fᵢₙ/R, where R is a fraction greater than 1, the method including receiving input samples at the input rate Fᵢₙ; multiplying, using a multiplier block, the received input samples by respective delta values, where each of the delta values corresponds to a time interval from a sample time of one of output samples at the output rate Fₒᵤₜ; integrating outputs of the multiplier block in groups, where each of the groups is associated with a respective one of a plurality of filters; generating, in parallel, N delta values of the delta values and N first-in-first-out (FIFO) write pointers based on R, where N is an integer greater than 1; storing integrated samples associated with each filter of the plurality of filters to a respective one of a plurality of FIFO buffers according to the N FIFO write pointers; and outputting the stored samples from the FIFO buffers to respective filters of the plurality of filters.

In Example 32, the method of Example 31 can optionally include where the generating the N delta values and the N FIFO write pointers is based on a clock signal divided from Fᵢₙ based on N, and where the N delta values and the N FIFO write pointers are generated in parallel within one clock cycle of the clock signal.

In Example 33, the method of any one of Examples 31-32 can optionally include where a number of the outputs for the integrating is based on an overflow factor dependent on R.

In Example 34, the method of any one of Examples 31-33 can optionally include where the integrating further includes multiplying a first output of the outputs of the multiplier block by a value based on a comparison between two successive FIFO write pointers of the N FIFO write pointers to produce a product value; and summing a second output of the outputs of the multiplier block.

In Example 35, the method of any one of Examples 31-34 can optionally include where the generating the N delta values and the N FIFO write pointers includes incrementing a base accumulation value by N×1/R; and generating the N delta values and the N FIFO write pointers based on the incremented base accumulation value.

In Example 36, the method of any one of Examples 31-35 can optionally include where the generating the N delta values and the N FIFO write pointers further includes applying a modulo operation to the base accumulation value before the incrementing.

In Example 37, the method of any one of Examples 31-36 can optionally include where the generating the N delta values and the N FIFO write pointers further includes: generating the N delta values by adding k×1/R to the incremented base accumulation value, where k varies from 0 to N−1.

Variations and Implementations

While embodiments of the present disclosure were described above with references to exemplary implementations as shown in FIGS. 1-4, 5A, and 6-21, a person skilled in the art will realize that the various teachings described above are applicable to a large variety of other implementations.

In certain contexts, the features discussed herein can be applicable to automotive systems, safety-critical industrial applications, medical systems, scientific instrumentation, wireless and wired communications, radio, radar, industrial process control, audio and video equipment, current sensing, instrumentation (which can be highly precise), and other digital-processing-based systems.

In the discussions of the embodiments above, components of a system, such as filters, integration and dump circuitry, adders, multipliers, FIFOs, and/or other components can readily be replaced, substituted, or otherwise modified in order to accommodate particular circuitry needs. Moreover, it should be noted that the use of complementary electronic devices, hardware, software, etc., offer an equally viable option for implementing the teachings of the present disclosure related to arbitrary/fractional sample rate conversion, in various communication systems.

Parts of various systems for implementing arbitrary/fractional sample rate conversion as proposed herein can include electronic circuitry to perform the functions described herein. In some cases, one or more parts of the system can be provided by a processor specially configured for carrying out the functions described herein. For instance, the processor may include one or more application specific components, or may include programmable logic gates which are configured to carry out the functions describe herein. The circuitry can operate in analog domain, digital domain, or in a mixed-signal domain. In some instances, the processor may be configured to carrying out the functions described herein by executing one or more instructions stored on a non-transitory computer-readable storage medium.

In one example embodiment, any number of electrical circuits of the present figures may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of DSPs, microprocessors, supporting chipsets, etc.), computer-readable non-transitory memory elements, etc. can be suitably coupled to the board based on particular configuration needs, processing demands, computer designs, etc. Other components such as external storage, additional sensors, controllers for audio/video display, and peripheral devices may be attached to the board as plug-in cards, via cables, or integrated into the board itself. In various embodiments, the functionalities described herein may be implemented in emulation form as software or firmware running within one or more configurable (e.g., programmable) elements arranged in a structure that supports these functions. The software or firmware providing the emulation may be provided on non-transitory computer-readable storage medium comprising instructions to allow a processor to carry out those functionalities.

In another example embodiment, the electrical circuits of the present figures may be implemented as stand-alone modules (e.g., a device with associated components and circuitry configured to perform a specific application or function) or implemented as plug-in modules into application specific hardware of electronic devices. Note that particular embodiments of the present disclosure may be readily included in a system on chip (SOC) package, either in part, or in whole. An SOC represents an IC that integrates components of a computer or other electronic system into a single chip. It may contain digital, analog, mixed-signal, and often RF functions: all of which may be provided on a single chip substrate. Other embodiments may include a multi-chip-module (MCM), with a plurality of separate ICs located within a single electronic package and configured to interact closely with each other through the electronic package.

It is also imperative to note that all of the specifications, dimensions, and relationships outlined herein (e.g., the number of components in the FSRCs 500, 600, 700, 1000, and 1600 shown in FIGS. 5A, 6, 7, 10, and 16, the accumulators 800, 900, 1300 shown in FIGS. 8, 9, 13, and/or the implementation schemes shown in FIGS. 14-15 and 17-18) have only been offered for purposes of example and teaching only. Such information may be varied considerably without departing from the spirit of the present disclosure, or the scope of the appended claims. It should be appreciated that the system can be consolidated in any suitable manner. Along similar design alternatives, any of the illustrated circuits, components, modules, and elements of the present figures may be combined in various possible configurations, all of which are clearly within the broad scope of this specification. In the foregoing description, example embodiments have been described with reference to particular processor and/or component arrangements. Various modifications and changes may be made to such embodiments without departing from the scope of the appended claims. The description and drawings are, accordingly, to be regarded in an illustrative rather than in a restrictive sense.

Note that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this Specification. In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

Note that in this Specification, references to various features (e.g., elements, structures, modules, components, steps, operations, characteristics, etc.) included in “one embodiment”, “example embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments. Also, as used herein, including in the claims, “or” as used in a list of items (for example, a list of items prefaced by a phrase such as “at least one of” or “one or more of”) indicates an inclusive list such that, for example, a list of [at least one of A, B, or C] means A or B or C or AB or AC or BC or ABC (i.e., A and B and C).

Various aspects of the illustrative embodiments are described using terms commonly employed by those skilled in the art to convey the substance of their work to others skilled in the art. For example, the term “connected” means a direct electrical connection between the things that are connected, without any intermediary devices/components, while the term “coupled” means either a direct electrical connection between the things that are connected, or an indirect connection through one or more passive or active intermediary devices/components. In another example, the term “circuit” means one or more passive and/or active components that are arranged to cooperate with one another to provide a desired function. Also, as used herein, the terms “substantially,” “approximately,” “about,” etc., may be used to generally refer to being within +/−20% of a target value, e.g., within +/−10% of a target value, based on the context of a particular value as described herein or as known in the art.

Numerous other changes, substitutions, variations, alterations, and modifications may be ascertained to one skilled in the art and it is intended that the present disclosure encompass all such changes, substitutions, variations, alterations, and modifications as falling within the scope of the examples and appended claims. Note that all optional features of the apparatus described above may also be implemented with respect to the method or process described herein and specifics in the examples may be used anywhere in one or more embodiments.

1. A sample rate converter (SRC) for implementing a rate conversion R, wherein the SRC receives input samples at an input rate Fᵢₙ and outputs samples at an output rate Fₒᵤₜ=Fᵢₙ×R, and wherein R is a fractional value greater than 1, the SRC comprising:
a plurality of filters to process the received input samples;
a multiplier-adder block to generate the output samples for the SRC based on respective delta values and outputs of the plurality of filters, wherein each of the delta values is associated with a time interval from one of the received input samples; and
a plurality of buffers to buffer samples between the plurality of filters and the multiplier-adder block based at least in part on N buffer read pointers, where N is an integer greater than 1; and
resampler control circuitry to generate N delta values of the delta values and the N buffer read pointers in parallel based on R.

2. The SRC of claim 1, wherein each one of the plurality of filters is associated with a different polynomial order.

3. The SRC of claim 1, wherein each buffer of the plurality of buffers stores output samples of a respective one of the plurality of filters, and wherein the stored samples are read from each buffer based on the N buffer read pointers.

4. The SRC of claim 1, wherein:
the resampler control circuitry further comprises N multiplexers (MUXs), each of the N MUXs having inputs connected to respective outputs of a first buffer of the plurality of buffers and outputs connected to the multiplier-adder block; and
the resampler control circuitry further generates a selection signal to each of the N MUXs based on a respective one of the N buffer read pointers.

5. The SRC of claim 1, wherein the resampler control circuitry operates based on a clock signal divided from Fₒᵤₜ based on N, and wherein the N delta values and the N buffer read pointers are generated in parallel within one clock cycle of the clock signal.

6. The SRC of claim 1, wherein the resampler control circuitry increments a base accumulation value by N×1/R and generates the N delta values and the N buffer read pointers based on the incremented base accumulation value.

7. The SRC of claim 6, wherein the resampler control circuitry applies a modulo operation to the base accumulation value before the incrementing.

8. The SRC of claim 6, wherein the resampler control circuitry generates the N delta values by adding k×1/R to the incremented base accumulation value, where k varies from 0 to N−1.

9. The SRC of claim 1, wherein the resampler control circuitry comprises:
a base accumulator to increment a base accumulation value by N×1/R; and
N adders each generating one of the N delta values and an offset for a corresponding buffer read pointer of the N buffer read pointers by adding k×R_int to the incremented base accumulation value, where k varies from 0 to N−1 and R_int corresponds to 1/R represented as a P-bit integer value.

10. The SRC of claim 9, wherein an output of a first adder of the N adders includes:
a first bit portion corresponding to a respective one of the N delta values; and
a second bit portion corresponding to an offset for a respective one of the N buffer read pointers.

11. A sample rate converter (SRC) for implementing a rate conversion R, wherein the SRC receives input samples at an input rate Fᵢₙ and outputs samples at an output rate Fₒᵤₜ=Fᵢₙ/R, and wherein R is a fractional value greater than 1, the SRC comprising:
a multiplier block to multiply each of the received input samples by a respective one of delta values, wherein each of the delta values is associated with a time interval from a sample time of one of the SRC output samples;
integration and dump circuitry to sum outputs of the multiplier block; and
resampler control circuitry to generate N delta values of the delta values and N buffer write pointers in parallel, wherein N is an integer greater than 1;
a plurality of filters; and
a plurality of buffers to buffer samples between the integration and dump circuitry and the plurality of filters based at least in part on the N buffer write pointers.

12. The SRC of claim 11, wherein the integration and dump circuitry comprises a plurality of integration and dump sub-circuitries each coupled to a respective filter of the plurality of filters to generate a sample for input to the respective filter based on a sum of a first output and a second output of the outputs of the multiplier block.

13. The SRC of claim 11, wherein the integration and dump circuitry sums the outputs of the multiplier block by multiplying a first output of the outputs of the multiplier block by a value based on a comparison between two successive buffer write pointers of the N buffer write pointers to produce a product value and summing a second output of the outputs of the multiplier block.

14. The SRC of claim 11, wherein output samples of the integration and dump circuitry for each of the plurality of filters are stored at a respective one of the plurality of buffers based on the N buffer write pointers, and wherein the stored samples are read from each buffer for processing by a respective filter of the plurality of filters.

15. The SRC of claim 11, wherein the resampler control circuitry operates based on a clock signal divided from Fᵢₙ based on N, and wherein the N delta values and the N buffer write pointers are generated in parallel within one clock cycle of the clock signal.

16. The SRC of claim 11, wherein the resampler control circuitry:
applies a modulo operation to a base accumulation value;
increments the base accumulation value by N×1/R; and
generates the N delta values and the N buffer write pointers based on the incremented base accumulation value.

17. The SRC of claim 16, wherein the resampler control circuitry generates the N delta values by adding k×1/R to the incremented base accumulation value, where k varies from 0 to N−1.

18. A method for performing a sample rate conversion R with an input rate Fᵢₙ and output rate Fₒᵤₜ=Fᵢₙ× R, wherein R is a fraction greater than 1, the method comprising:
receiving input samples at the input rate Fᵢₙ;
processing the received input samples by a plurality of filters;
storing outputs samples of a first filter of the plurality of filters in a first-out (FIFO) buffer;
reading the stored samples from the FIFO buffer according to N FIFO read pointers;
generating rate-converted output samples at the output rate Fₒᵤₜ based on the read samples and respective delta values, wherein each of the delta values corresponds to a time interval from one of the received input samples; and
generating, in parallel, N delta values of the delta values and the N FIFO read pointers based on R, wherein N is an integer greater than 1.

19. The method of claim 18, wherein the generating the N delta values and the N FIFO read pointers is based on a clock signal divided from Fₒᵤₜ based on N, and wherein the N delta values and the N buffer read pointers are generated in parallel within one clock cycle of the clock signal.

20. The method of claim 18, wherein the generating the N delta values and the N FIFO read pointers comprises:
applying a modulo operation to a base accumulation value;
incrementing the base accumulation value by N×1/R; and
generating the N delta values and the N buffer read pointers by adding k×1/R to the incremented base accumulation value, where k varies from 0 to N−1.
